(19) United States
(12) Patent Application Publication
(10) Pub. No.: US 2023/0159752 A1
(43) Pub. Date: May 25, 2023

(54) RESIN COMPOSITION, FILM, OPTICAL FILTER, SOLID-STATE IMAGING ELEMENT, AND IMAGE DISPLAY DEVICE

(71) Applicant: FUJIFILM Corporation, Tokyo (JP)

(72) Inventors: Kazuya OOTA, Haibara-gun (JP); Akio MIZUNO, Haibara-gun (JP); Yutaro FUKAMI, Haibara-gun (JP); Shoichi NAKAMURA, Haibara-gun (JP)

(73) Assignee: FUJIFILM Corporation, Tokyo (JP)

(21) Appl. No.: 18/057,349

(22) Filed: Nov. 21, 2022

Related U.S. Application Data
(63) Continuation of application No. PCT/JP2021/018527, filed on May 17, 2021.

(30) Foreign Application Priority Data
May 22, 2020 (JP) 2020-089720

(51) Int. Cl. C08L 79/02; C08K 5/3475; C08J 5/18; G02B 5/20

(52) U.S. Cl. CPC C08L 79/02; C08K 5/3475; C08J 5/18; G02B 5/20; C08J 2379/02

(57) ABSTRACT

Provided are a resin composition including a pigment, a compound A which includes 3 or more basic groups in one molecule, has an amine value of 2.7 mmol/g or more, and has a molecular weight of 100 or more, and a resin having an acid group, in which the pigment is included in an amount of 40% by mass or more in a total solid content of the resin composition; a film formed of the resin composition; and an optical filter, a solid-state imaging element, and an image display device, which include the film.

### CROSS-REFERENCE TO RELATED APPLICATIONS

This application is a Continuation of PCT International Application No. PCT/JP2021/018527 filed on May 17, 2021, which claims priority under 35 U.S.C § 119(a) to Japanese Patent Application No. 2020-089720 filed on May 22, 2020. Each of the above application(s) is hereby expressly incorporated by reference, in its entirety, into the present application.

### BACKGROUND OF THE INVENTION

### 1. Field of the Invention

The present invention relates to a resin composition including a pigment. The present invention further relates to a film formed of the resin composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

The color filter is manufactured by using a resin composition including a coloring material. In addition, in a case where a pigment is used as the coloring material, the pigment is generally dispersed in the resin composition by using a pigment derivative, a dispersant, or the like.

Patent Literature 1 discloses an invention relating to a coloring composition for a color filter, which includes a xanthene-based coloring agent, an organic pigment, polyethyleneimine, and a binder resin.

Patent Literature 2 discloses an invention relating to a coloring composition for a color filter, which includes a pigment, a dispersant, a photopolymerizable monomer, and a photopolymerization initiator, in which the dispersant is a linear dispersant and a comb dispersant, and the photopolymerizable monomer includes a photopolymerization initiator having 3 or less polymerizable functional groups and a photopolymerization initiator having more than 3 polymerizable functional groups.

### 3. Citation List

### Patent Literature

[Patent Literature 1] JP2013-041145A
[Patent Literature 2] JP2019-184763A

### SUMMARY OF THE INVENTION

In recent years, there has been a strong demand for miniaturization and film-thinning in a solid-state imaging element. Therefore, in recent years, it has been desired to further reduce a thickness of a film including a pigment, such as a color filter, used in the solid-state imaging element. In order to achieve a thin film while maintaining desired spectral performance, it is necessary to increase a concentration of the pigment in a resin composition used for film formation.

In forming a film using the resin composition, a film may be formed using a resin composition stored at a low temperature.

However, as the concentration of the pigment in the total solid content of the resin composition increases, a viscosity of the resin composition tends to increase due to due to aggregation of the pigments in the resin composition during a storage of the resin composition. In particular, in a case where the resin composition having a high concentration of the pigment is stored at a low temperature environment, the viscosity of the resin composition tends to increase.

Therefore, an object of the present invention is to provide a resin composition having excellent storage stability at a low temperature. Another object of the present invention is to provide a film formed of the resin composition, an optical filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A resin composition comprising:

a pigment;

a compound A which includes 3 or more basic groups in one molecule, has an amine value of 2.7 mmol/g or more, and has a molecular weight of 100 or more; and

a resin having an acid group,

in which the pigment is included in an amount of 40% by mass or more in a total solid content of the resin composition.

<2> The resin composition according to <1>,

in which the basic group included in the compound A is an amino group.

<3> The resin composition according to <1> or <2>,

in which the amine value of the compound A is 15 mmol/g or more.

<4> The resin composition according to any one of <1> to <3>,

in which the compound A is a polyalkyleneimine.

<5> The resin composition according to any one of <1> to <3>,

in which the compound A is polyethyleneimine.

<6> The resin composition according to any one of <1> to <5>,

in which the molecular weight of the compound A is 2000 or less.

<7> The resin composition according to any one of <1> to <6>,

in which the pigment includes a chromatic pigment.

<8> The resin composition according to any one of <1> to <7>,

in which the pigment includes a pigment containing a metal atom.

<9> The resin composition according to any one of <1> to <8>,

in which the pigment includes a halogenated zinc phthalocyanine pigment.

<10> The resin composition according to any one of <1> to <9>,

in which the pigment is included in an amount of 60% by mass or more in the total solid content of the resin composition.

<11> The resin composition according to any one of <1> to <10>, further comprising:

a pigment derivative.

<12> A film formed of the resin composition according to any one of <1> to <11>.

<13> An optical filter comprising:

the film according to <12>.

<14> A solid-state imaging element comprising:

the film according to <12>.

<15> An image display device comprising:

the film according to <12>.

According to the present invention, it is possible to provide a resin composition having excellent storage stability at a low temperature. It is also possible to provide a film formed of the resin composition, an optical filter, a solid-state imaging element, and an image display device.

### DESCRIPTION OF THE PREFERRED EMBODIMENTS

Hereinafter, the details of the present invention will be described.

In the present specification, numerical values represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a structural formula, Me represents a methyl group, Et represents an ethyl group, Bu represents a butyl group, Pr represents a propyl group, and Ph represents a phenyl group.

In the present specification, a weight-average molecular weight and a number-average molecular weight are values in terms of polystyrene through measurement by a gel permeation chromatography (GPC) method.

In the present specification, near-infrared rays denote light having a wavelength in a range of 700 to 2500 nm.

In the present specification, a total solid content denotes the total mass of all the components of the composition excluding a solvent.

In the present specification, a pigment means a coloring material which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, a dye means a coloring material which is easily soluble in a solvent.

In the present specification, the term “step” denotes not only an individual step but also a step which is not clearly distinguishable from another step as long as an effect expected from the step can be achieved.

<Resin Composition>

A resin composition according to an embodiment of the present invention is a resin composition including a pigment, a compound A which includes 3 or more basic groups in one molecule, has an amine value of 2.7 mmol/g or more, and has a molecular weight of 100 or more, and a resin having an acid group, in which the pigment is included in an amount of 40% by mass or more in a total solid content of the resin composition.

Although the content of the pigment in the total solid content is 40% by mass or more, the resin composition according to the embodiment of the present invention has excellent storage stability, and even in a case where the resin composition is stored at a low temperature for a long period of time, an increase in viscosity can be suppressed. The reason for obtaining such an effect is presumed as follows. Since the resin composition according to the embodiment of the present invention includes the pigment, the above-described compound A, and the resin having an acid group, in the resin composition, a part of the basic groups of the compound A is coordinated to a surface of the pigment and a basic group not coordinated to the pigment among the 3 or more basic groups of the compound A interact with the acid group of the resin having an acid group, and it is presumed that a network structure of pigment-compound A-resin having an acid group is formed in the resin composition. By forming such a network structure in the resin composition, it is presumed that aggregation of pigments included in the resin composition can be effectively suppressed, and excellent storage stability is obtained.

In particular, a pigment containing a metal atom, such as a halogenated zinc phthalocyanine pigment, tends to aggregate easily, and the viscosity of the resin composition tends to increase during storage, but even in a case where the pigment containing a metal atom, such as a halogenated zinc phthalocyanine pigment, is used as the pigment, a resin composition having excellent storage stability can be obtained. Therefore, the effects of the present invention are remarkably obtained in a case where the pigment containing a metal atom, such as a halogenated zinc phthalocyanine pigment, is used. The reason for obtaining such an effect is presumed that the basic group of the compound A is easily coordinated to the metal atom of the pigment, and the above-described network structure is easily formed.

In addition, by using the resin composition according to the embodiment of the present invention, it is possible to form a film in which generation of foreign matter is suppressed. It is presumed that the above-described network structure is formed even in the film, and movement of the pigment in the film can be suppressed, and as a result, the generation of foreign matter can be suppressed.

In addition, since the aggregation of the pigment in the film can be suppressed, variation in spectral characteristics and the like can also be suppressed.

The resin composition according to the embodiment of the present invention is preferably used as a resin composition for an optical filter. Examples of the optical filter include a color filter, a near-infrared transmitting filter, and a near-infrared cut filter, and a color filter is preferable. In addition, the resin composition according to the embodiment of the present invention is preferably used for a solid-state imaging element. More specifically, the resin composition according to the embodiment of the present invention is preferably used as a resin composition for an optical filter used for a solid-state imaging element, and more preferably used as a resin composition for forming a colored pixel of a color filter used for a solid-state imaging element.

Examples of the color filter include a filter having a colored pixel which transmits light having a specific wavelength. Examples of the colored pixel include a red pixel, a green pixel, a blue pixel, a magenta pixel, a cyan pixel, and a yellow pixel, and a green pixel or a cyan pixel is preferable and a green pixel is more preferable. The colored pixel of the color filter can be formed using a resin composition including a chromatic pigment.

The maximal absorption wavelength of the near-infrared cut filter is preferably in a wavelength range of 700 to 1800 nm, more preferably in a wavelength range of 700 to 1300 nm, and still more preferably in a wavelength range of 700 to 1000 nm. In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near-infrared cut filter, absorbance Aₘₐₓ/absorbance A₅₅₀, which is a ratio of an absorbance Aₘₐₓ at a maximal absorption wavelength to an absorbance A₅₅₀ at a wavelength of 550 nm, is preferably 20 to 500, more preferably 50 to 500, still more preferably 70 to 450, and particularly preferably 100 to 400. The near-infrared cut filter can be formed using a resin composition including a near-infrared absorbing pigment.

The near-infrared transmitting filter is a filter which transmits at least a part of near-infrared rays. The near-infrared transmitting filter may be a filter (transparent film) which transmits both visible light and near-infrared ray, or may be a filter which shields at least a part of visible light and transmits at least a part of near-infrared rays. Preferred examples of the near-infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmitting filter is preferably a filter which satisfies any one of the following spectral characteristics (1) to (5).

(1): filter in which the maximum value of a transmittance in a wavelength range of 400 to 640 nm is 20% or less (preferably 15% or less and more preferably 10% or less) and the minimum value of a transmittance in a wavelength range of 800 to 1500 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1500 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1500 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1500 nm is 70% or more (preferably 75% or more and more preferably 80% or more).

(5): filter in which the maximum value of a transmittance in a wavelength range of 400 to 1050 nm is 20% or less (preferably 15% or less and more preferably 10% or less) and the minimum value of a transmittance in a wavelength range of 1200 to 1500 nm is 70% or more (preferably 75% or more and more preferably 80% or more).

The resin composition according to the embodiment of the present invention can also be used for a light-shielding film or the like.

The concentration of solid contents of the resin composition according to the embodiment of the present invention is preferably 5% to 30% by mass. The lower limit is preferably 7.5% by mass or more and more preferably 10% by mass or more. The upper limit is preferably 25% by mass or less, more preferably 20% by mass or less, and still more preferably 15% by mass or less.

Hereinafter, the respective components used in the resin composition according to the embodiment of the present invention will be described.

<<Pigment>>

The resin composition according to the embodiment of the present invention includes a pigment. Examples of the pigment include a white pigment, a black pigment, a chromatic pigment, and a near-infrared absorbing pigment. In the present specification, the white pigment includes not only a pure white pigment but also a bright gray (for example, grayish-white, light gray, and the like) pigment close to white.

In a case where the resin composition is used for a color filter, a chromatic pigment is used as the pigment. As the chromatic pigment, one kind may be included, or two or more kinds may be included. In addition, in a case where the resin composition is used for forming a near-infrared cut filter, a near-infrared absorbing pigment is used as the pigment. As the near-infrared absorbing pigment, one kind may be included, or two or more kinds may be included. In addition, in a case where a pixel for a near-infrared transmitting filter is formed from the resin composition, as the pigment, two or more kinds of chromatic pigments are used in combination, or a black pigment is used.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the resin composition is good. In the present invention, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is an arithmetic average of the primary particle diameters with respect to 400 primary particles of the pigment. In addition, the primary particle of the pigment refers to a particle which is independent without aggregation.

From the reason that the effects of the present invention are exhibited more remarkably, the pigment used in the present invention is preferably a pigment having a metal atom and more preferably an organic pigment having a metal atom. Examples of the organic pigment having a metal atom include an azomethine metal complex, an azo metal complex pigment, and a metal phthalocyanine pigment, and an azomethine metal complex or a metal phthalocyanine pigment is preferable, and a metal phthalocyanine pigment is more preferable. In addition, the pigment having a metal atom is preferably a chromatic pigment. According to this aspect, since the aggregation of the pigment in the film can be suppressed, variation in spectral characteristics and the like can also be suppressed.

Examples of the azomethine metal complex include Color Index (C. I.) Pigment Yellow 117 and 129.

Examples of the azo metal complex pigment include C. I. Pigment Yellow 150. In addition, as the azo metal complex pigment, an azobarbiturate nickel complex pigment having the following structure can also be used.

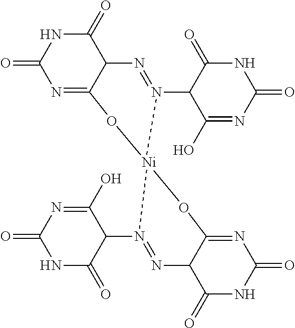

Examples of the metal phthalocyanine pigment include a copper phthalocyanine pigment, a zinc phthalocyanine pigment, and an aluminum phthalocyanine pigment, and a halogenated copper phthalocyanine pigment, a halogenated zinc phthalocyanine pigment, or a halogenated aluminum phthalocyanine pigment is preferable, and a halogenated zinc phthalocyanine pigment is more preferable. The halogenated zinc phthalocyanine pigment tends to aggregate in the resin composition and storage stability of a resin composition including the halogenated zinc phthalocyanine pigment tends to be low, but with the resin composition according to the embodiment of the present invention, even in a case where the halogenated zinc phthalocyanine pigment is used, excellent storage stability is exhibited. Therefore, the effects of the present invention are particularly remarkably exhibited in a case where the halogenated zinc phthalocyanine pigment is used.

Here, the copper phthalocyanine pigment is a phthalocyanine pigment having a copper atom as a central metal. In addition, the halogenated copper phthalocyanine pigment is a halogenated phthalocyanine pigment having a copper atom as a central metal. In addition, the halogenated phthalocyanine pigment is a phthalocyanine pigment having a halogen atom as a substituent.

In addition, the zinc phthalocyanine pigment is a phthalocyanine pigment having a zinc atom as a central metal. In addition, the halogenated zinc phthalocyanine pigment is a halogenated phthalocyanine pigment having a zinc atom as a central metal.

In addition, the aluminum phthalocyanine pigment is a phthalocyanine pigment having an aluminum atom as a central metal. In addition, the halogenated aluminum phthalocyanine pigment is a halogenated phthalocyanine pigment having an aluminum atom as a central metal.

Specific examples of the metal phthalocyanine pigment include green pigments such as C. I. Pigment Green 7, 36, 58, 59, 62, and 63 and blue pigments such as C. I. Pigment Blue 15, 15:1, 15:2, 15:3, 15:4, and 15:6.

Hereinafter the pigment used in the present invention will be described in more detail.

(Chromatic Pigment)

The chromatic pigment is not particularly limited, and a known chromatic pigment can be used. Examples of the chromatic pigment include a pigment having a maximal absorption wavelength in a wavelength range of 400 to 700 nm. Examples thereof include a yellow pigment, an orange pigment, a red pigment, a green pigment, a violet pigment, and a blue pigment. Specific examples of these pigments include the following pigments.

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, as the green pigment, a halogenated zinc phthalocyanine pigment in which an average number of halogen atoms in one molecule is 10 to 14, an average number of bromine atoms in one molecule is 8 to 12, and an average number of chlorine atoms in one molecule is 2 to 5 can also be used. Specific examples thereof include phthalocyanine pigments described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue pigment, an aluminum phthalocyanine pigment having a phosphorus atom can also be used. Specific examples thereof include the compounds described in paragraph Nos. 0022 to 0030 of JP2012-247591A and paragraph No. 0047 of JP2011-157478A.

In addition, as the yellow pigment, an azobarbiturate nickel complex pigment having the above-described structure can also be used. In addition, as the yellow pigment, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, a compound represented by Formula (QP1), a compound represented by Formula (QP2), compounds described in KR10-2014-0034963A, compounds described in JP2017-095706A, compounds described in TW2019-20495A, compounds described in JP6607427B, compounds described in JP2020-033525A, compounds described in JP2020-033524A, compounds described in JP2020-033523A, compounds described in JP2020-033522A, compounds described in JP2020-033521A, compounds described in WO2020/045200A, compounds described in WO2020/045199A, and compounds described in WO2020/045197A can also be used. In addition, from the viewpoint of improving a color value, a multimerized compound of these compounds is also preferably used.

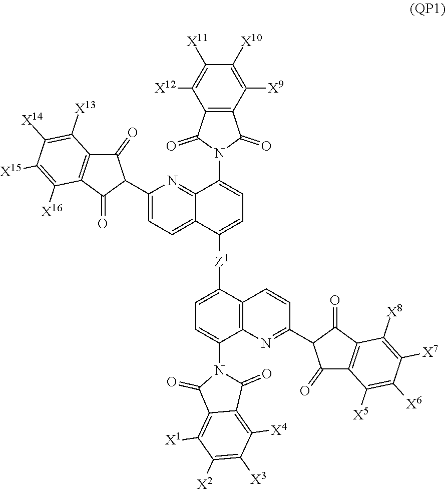

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

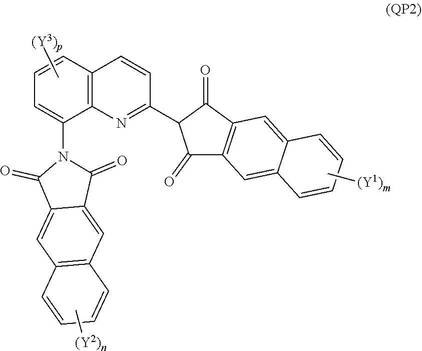

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, red pigments described in JP6516119B, red pigments described in JP6525101B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

Regarding diffraction angles preferably possessed by various pigments, descriptions of JP6561862B, JP6413872B, JP6281345B, JP2020-026503A, and JP2020-033526A can be referred to, the contents of which are incorporated herein by reference.

The chromatic pigment may be used in combination of two or more kinds thereof. For example, in a case where the resin composition according to the embodiment of the present invention is used for forming a green pixel of a color filter, it is preferable to use a green pigment and a yellow pigment in combination. As the green pigment, C. I. Pigment Green 7, 36, 58, 59, or 63 is preferable, and C. I. Pigment Green 58 is more preferable. As the yellow pigment, C. I. Pigment Yellow 129 or 150 is preferable, and C. I. Pigment Yellow 150 is more preferable.

In addition, in a case where the chromatic pigment is used in combination of two or more kinds thereof, the combination of two or more chromatic pigments may form black. Examples of such a combination include the following aspects (1) to (7). In a case where two or more chromatic pigments are included in the resin composition and the combination of two or more chromatic pigments forms black, the resin composition according to the embodiment of the present invention can be preferably used as a resin composition for forming the near-infrared transmitting filter.

(1) aspect in which a red pigment and a blue pigment are contained.

(2) aspect in which a red pigment, a blue pigment, and a yellow pigment are contained.

(3) aspect in which a red pigment, a blue pigment, a yellow pigment, and a violet pigment are contained.

(4) aspect in which a red pigment, a blue pigment, a yellow pigment, a violet pigment, and a green pigment are contained.

(5) aspect in which a red pigment, a blue pigment, a yellow pigment, and a green pigment are contained.

(6) aspect in which a red pigment, a blue pigment, and a green pigment are contained.

(7) aspect in which a yellow pigment and a violet pigment are contained.

(White Pigment)

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published in Jun. 25, 1991, published by Gihodo Shuppan Co., Ltd.” can also be used.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

(Black Pigment)

The black pigment is not particularly limited, and a known black pigment can be used. Examples thereof include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include C. I. Pigment Black 1 and 7. It is preferable that the titanium black has a small primary particle diameter of the individual particles and has a small average primary particle diameter. Specifically, an average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

(Near-Infrared Absorbing Pigment)

The near-infrared absorbing pigment is preferably an organic pigment. In addition, the near-infrared absorbing pigment preferably has a maximal absorption wavelength in a wavelength range of more than 700 nm and 1400 nm or less. In addition, the maximal absorption wavelength of the near-infrared absorbing pigment is preferably 1200 nm or less, more preferably 1000 nm or less, and still more preferably 950 nm or less. In addition, in the near-infrared absorbing pigment, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing pigment excellent in visible transparency and near infrared shielding properties can be obtained. In the present invention, the maximal absorption wavelength of the near-infrared absorbing pigment and values of absorbance at each wavelength are values obtained from an absorption spectrum of a film formed by using a resin composition including the near-infrared absorbing pigment.

The near-infrared absorbing pigment is not particularly limited, and examples thereof include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. Among these, at least one compound selected from a pyrrolopyrrole compound, a squarylium compound, a cyanine compound, a phthalocyanine compound, or a naphthalocyanine compound is preferable, and a pyrrolopyrrole compound or a squarylium compound is more preferable, and a pyrrolopyrrole compound is particularly preferable. Specific examples of the near-infrared absorbing pigment include compounds described in Examples described later.

The content of the pigment in the total solid content of the resin composition is 40% by mass or more, preferably 45% by mass or more, more preferably 50% by mass or more, still more preferably 55% by mass or more, and even more preferably 60% by mass or more. The upper limit is preferably 80% by mass or less, more preferably 75% by mass or less, and still more preferably 70% by mass or less.

In addition, a content of the pigment containing a metal atom in the pigment is preferably 30% by mass or more, more preferably 40% by mass or more, and still more preferably 50% by mass or more. The upper limit may be 100% by mass or less, 90% by mass or less, or 80% by mass or less.

In addition, a content of the chromatic pigment in the pigment is preferably 30% to 100% by mass, more preferably 40% to 100% by mass, and still more preferably 50% to 100% by mass.

In addition, a content of the halogenated zinc phthalocyanine pigment in the pigment is preferably 30% by mass or more, more preferably 40% by mass or more, and still more preferably 50% by mass or more. The upper limit may be 100% by mass or less, 90% by mass or less, or 80% by mass or less.

<<Dye>>

The resin composition according to the embodiment of the present invention may include a dye. As the dye, a known dye can be used without any particular limitation. Examples of the dye include a chromatic dye, a black dye, and a near-infrared absorbing dye. As the dye, a known dye can be used. In addition, methine dyes described in JP2019-073695A, methine dyes described in JP2019-073696A, methine dyes described in JP2019-073697A, and methine dyes described in JP2019-073698A can also be used. In addition, as the dye, a coloring agent multimer can also be used. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. A weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, JP2016-102191A, WO2016/031442A, or the like can also be used.

A content of the dye in the total solid content of the resin composition is preferably 50% by mass or less, more preferably 40% by mass or less, and still more preferably 30% by mass or less. In addition, the content of the dye in the resin composition is preferably 100 parts by mass or less, more preferably 80 parts by mass or less, and still more preferably 60 parts by mass or less with respect to 100 parts by mass of the pigment.

It is also possible that the resin composition according to the embodiment of the present invention does not substantially contain the dye. According to this aspect, a proportion of the pigment in the resin composition can be increased, and the effect of suppressing the aggregation of the pigment can be obtained more remarkably. In the present specification, the case where the resin composition does not substantially contain the dye means that the content of the dye in the total solid content of the resin composition is 0.1% by mass or less, preferably 0.01% by mass or less, and more preferably 0% by mass.

<<Resin>>

The resin composition according to the embodiment of the present invention contains a resin. The resin is blended in, for example, an application for dispersing the pigment in the resin composition or an application as a binder. Mainly, a resin which is used for dispersing the pigment is also referred to as a dispersant. However, such applications of the resin are merely exemplary, and the resin can also be used for other purposes in addition to such applications.

A weight-average molecular weight (Mw) of the resin is preferably 3000 to 2000000. The upper limit is more preferably 1000000 or less and still more preferably 500000 or less. The lower limit is more preferably 4000 or more and particularly preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, resins described in paragraphs 0041 to 0060 of JP2017-206689A, resins described in paragraphs 0022 to 0071 of JP2018-010856A, resins described in JP2017-057265A, resins described in JP2017-032685A, resins described in JP2017-075248A, and resins described in JP2017-066240A can also be used.

(Resin Having Acid Group)

In the resin composition according to the embodiment of the present invention, a resin having an acid group is used as the resin. The resin composition according to the embodiment of the present invention preferably includes the resin having an acid group as a dispersant. According to this aspect, the above-described network structure between the pigment, the compound A, and the resin having an acid group is likely to be formed, and the storage stability of the resin composition can be more effectively improved. The resin having an acid group may be included as a binder. The resin having an acid group can be used, for example, as an alkali-soluble resin.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. In addition, as the resin having an acid group, a commercially available product may also be used. In addition, a method of introducing the acid group into the resin is not particularly limited, and examples thereof include the method described in JP6349629B. Further, examples of the method of introducing the acid group into the resin include a method of introducing an acid group by reacting an acid anhydride with a hydroxy group generated by a ring-opening reaction of an epoxy group.

Examples of the acid group included in the resin having an acid group include a carboxyl group, a phosphoric acid group, a sulfo group, and a phenolic hydroxy group, and a carboxyl group is preferable.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

An acid value of the resin having an acid group is preferably 30 to 500 mgKOH/g. The lower limit is preferably 40 mgKOH/g or more and more preferably 50 mgKOH/g or more. The upper limit is more preferably 400 mgKOH/g or less, still more preferably 300 mgKOH/g or less, and particularly preferably 200 mgKOH/g or less. A weight-average molecular weight (Mw) of the resin having an acid group is preferably 5000 to 100000 and more preferably 5000 to 50000. In addition, the number-average molecular weight (Mn) of the resin having an acid group is preferably 1000 to 20000.

It is also preferable that the resin having an acid group includes a repeating unit derived from a monomer component including a compound represented by Formula (ED1) and/or a compound represented by Formula (ED2) (hereinafter, these compounds may be referred to as an “ether dimer”).

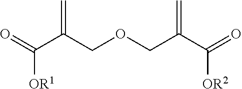

In Formula (ED1), R¹ and R² each independently represent a hydrogen atom or a hydrocarbon group having 1 to 25 carbon atoms, which may have a substituent.

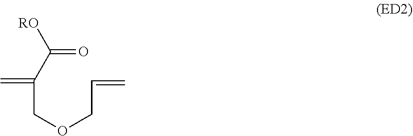

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

Specific examples of the ether dimer can be found in paragraph “0317” of JP2013-029760A, the content of which is incorporated herein by reference.

It is also preferable that the resin having an acid group includes a repeating unit derived from a compound represented by Formula (X).

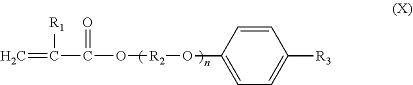

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

The resin having an acid group also preferably includes a repeating unit having a polymerizable group. Examples of the polymerizable group include an ethylenically unsaturated bond-containing group and a cyclic ether group, and an ethylenically unsaturated bond-containing group is preferable. Examples of the ethylenically unsaturated bond-containing group include a vinyl group, a (meth)allyl group, and a (meth)acryloyl group. Examples of the cyclic ether group include an epoxy group and an oxetanyl group.

The resin having an acid group is also preferably a graft resin having an acid group (hereinafter, also referred to as an acidic graft resin). According to this aspect, dispersibility of the pigment can be further improved, and the storage stability of the resin composition can be further improved. The acidic graft resin can be preferably used as a dispersant. Here, the graft resin means a resin including a repeating unit having a graft chain. In addition, the graft chain means a polymer chain branched from the main chain of the repeating unit. In the graft chain, the number of atoms excluding the hydrogen atoms is preferably 40 to 10000, the number of atoms excluding the hydrogen atoms is more preferably 50 to 2000, and the number of atoms excluding the hydrogen atoms is still more preferably 60 to 500.

The graft chain preferably includes at least one structure selected from a polyester chain, a polyether chain, a poly(meth)acryl chain, a polyurethane chain, a polyurea chain, or a polyamide chain, and more preferably includes at least one structure selected from a polyester chain, a polyether chain, or a poly(meth)acryl chain.

A terminal structure of the graft chain is not particularly limited. The terminal structure may be a hydrogen atom or a substituent. Examples of the substituent include an alkyl group, an aryl group, a heteroaryl group, an alkoxy group, an aryloxy group, a heteroaryloxy group, an alkylthioether group, an arylthioether group, a heteroarylthioether group, a hydroxy group, and an amino group. Among these, from the viewpoint of improvement of the dispersibility of the pigment or the like, a group having a steric repulsion effect is preferable, and an alkyl group or alkoxy group having 5 to 24 carbon atoms is preferable. The alkyl group and the alkoxy group may be linear, branched, or cyclic, and are preferably linear or branched.

The weight-average molecular weight of the graft chain is preferably 500 to 10000. The upper limit is preferably 8000 or less and more preferably 6000 or less. The lower limit is preferably 1000 or more and more preferably 1500 or more. In the present specification, the weight-average molecular weight of the graft chain is a value calculated from the weight-average molecular weight of the raw material monomer used for the polymerization of the repeating unit having the graft chain. For example, the repeating unit having the graft chain can be formed by polymerizing a macromonomer. Here, the macromonomer means a polymer compound in which a polymerizable group is introduced at a polymer terminal. In addition, as the value of the weight-average molecular weight of the raw material monomer, a value in terms of polystyrene through measurement by a gel permeation chromatography (GPC) method is used.

Examples of the acid group included in the acidic graft resin include a carboxyl group, a sulfo group, and a phosphoric acid group, and from the viewpoint of dispersibility of the pigment, a carboxyl group is preferable. An acid value of the acidic graft resin is preferably 20 to 150 mgKOH/g. The upper limit is preferably 130 mgKOH/g or less and more preferably 110 mgKOH/g or less. The lower limit is preferably 30 mgKOH/g or more and more preferably 40 mgKOH/g or more.

A weight-average molecular weight of the acidic graft resin is preferably 5000 to 100000, more preferably 10000 to 50000, and still more preferably 10000 to 30000. A number-average molecular weight (Mn) of the acidic graft resin is preferably 2500 to 50000, more preferably 5000 to 30000, and still more preferably 5000 to 15000.

The acidic graft resin is preferably a resin including a repeating unit having a graft chain and a repeating unit having an acid group. In addition, in all the repeating units of the acidic graft resin, the acidic graft resin preferably includes 1 mol % or more of the repeating unit having a graft chain, more preferably contains 2 mol % or more thereof, and still more preferably contains 3 mol % or more thereof. The upper limit may be 90 mol %, 80 mol % or less, 70 mol % or less, 60 mol % or less, or 50 mol % or less. In addition, in all the repeating units of the acidic graft resin, the acidic graft resin preferably includes 1 mol % or more of the repeating unit having an acid group, more preferably contains 2 mol % or more thereof, and still more preferably contains 3 mol % or more thereof. The upper limit may be 90 mol %, 80 mol % or less, 70 mol % or less, 60 mol % or less, or 50 mol % or less.

The acidic graft resin may further include a repeating unit other than those described above. Examples of other repeating units include a repeating unit having a polymerizable group. Examples of the polymerizable group include an ethylenically unsaturated bond-containing group and a cyclic ether group.

Specific examples of the acidic graft resin include resins described in paragraph Nos. 0025 to 0094 of JP2012-255128A and resins having structures described in Examples described later.

As the resin having an acid group, the resin composition according to the embodiment of the present invention also preferably includes a resin (hereinafter, also referred to as a resin Ac) having an aromatic carboxyl group. The resin Ac may include the aromatic carboxyl group in the main chain of the repeating unit, or in the side chain of the repeating unit. It is preferable that the aromatic carboxyl group is included in the main chain of the repeating unit. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) and a repeating unit represented by Formula (Ac-2).

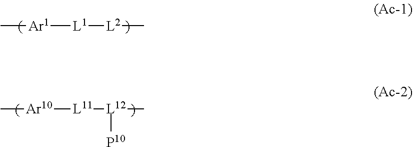

In Formula (Ac-1), Ar¹ represents a group including an aromatic carboxyl group, L¹ represents —COO— or —CONH—, and L² represents a divalent linking group.

In Formula (Ac-2), Ar¹⁰ represents a group including an aromatic carboxyl group, L¹¹ represents —COO— or —CONH—, L′² represents a trivalent linking group, and P¹⁰ represents a polymer chain.

In Formula (Ac-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

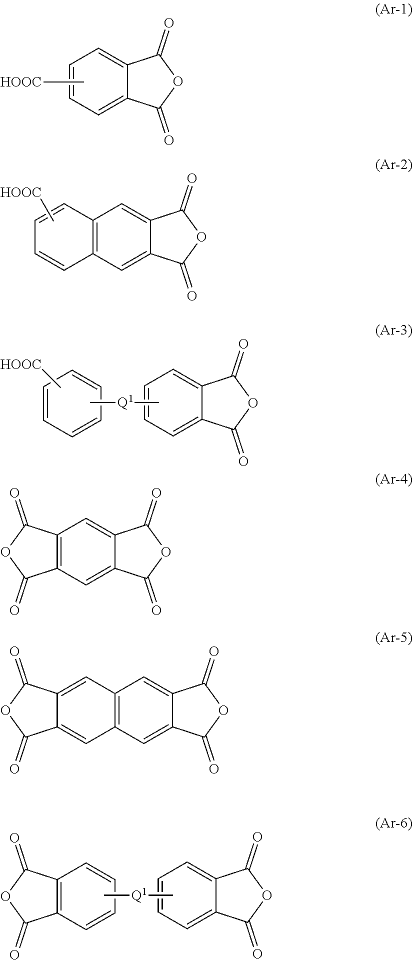

In the formulae, Q′ represents a single bond, —O—, —CO—, —COOCH₂CH₂OCO—, —SO₂—, —C(CF₃)₂—, a group represented by Formula (Q-1), or a group represented by Formula (Q-2).

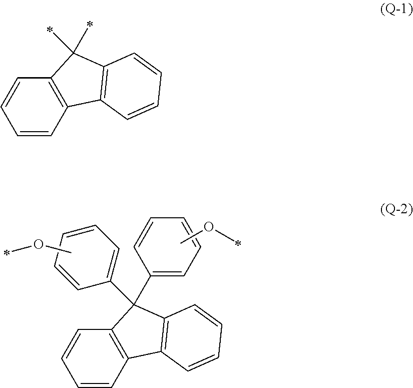

The group including an aromatic carboxyl group, which is represented by Ar¹, may have a polymerizable group. Examples of the polymerizable group include an ethylenically unsaturated bond-containing group and a cyclic ether group, and an ethylenically unsaturated bond-containing group is preferable. Specific examples of the group including an aromatic carboxyl group represented by Ar¹ include a group represented by Formula (Ar-11), a group represented by Formula (Ar-12), and a group represented by Formula (Ar-13).

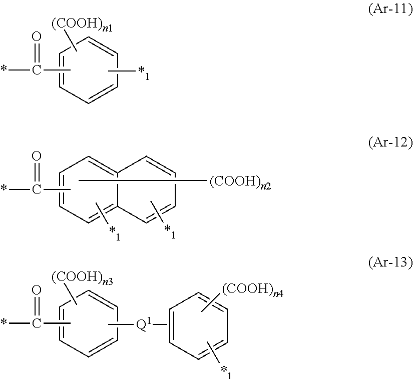

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formulae (Ar-11) to (Ar-13), *1 represents a bonding position with L¹.

In Formula (Ac-1), L¹ represents —COO— or —CONH—, preferably —COO—.

In Formula (Ac-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by -L^{2a}-O—. Examples of Lea include an alkylene group; an arylene group; a group formed by a combination of an alkylene group and an arylene group; and a group formed by a combination of at least one selected from an alkylene group or an arylene group, and at least one selected from —O—, —CO—, —COO—, —OCO—, —NH—, or —S—, and an alkylene group is preferable. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxyl group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L¹²-2).

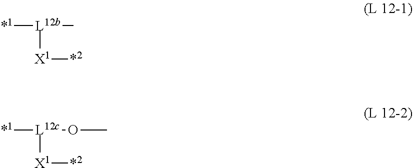

In Formula (L¹²-1), L^{12b} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L¹²-2), L^{12c} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxyl group is a resin having the repeating unit represented by Formula (Ac-2), this resin is preferably used as a dispersant.

The polymer chain represented by P¹⁰ may include a polymerizable group. Examples of the polymerizable group include an ethylenically unsaturated bond-containing group and a cyclic ether group, and an ethylenically unsaturated bond-containing group is preferable.

In Formula (Ac-2), the polymer chain represented by P¹⁰ is preferably a polymer chain including a repeating unit represented by Formulae (P-1) to (P-5), and more preferably a polymer chain including a repeating unit represented by (P-5).

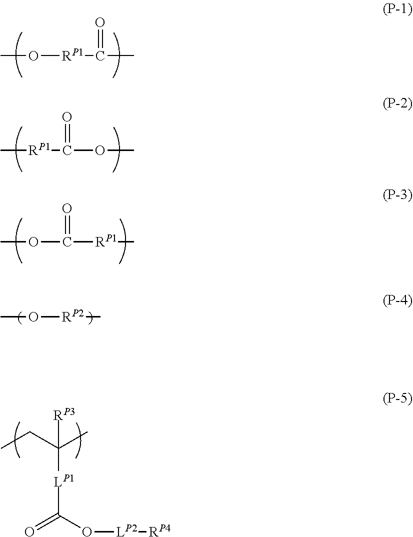

In the formulae, R^{P1} and R^{P2} each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{P3} represents a hydrogen atom or a methyl group.

In the formulae, LP′ represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxyl group, an alkyl group, an aryl group, a heteroaryl group, an alkoxy group, an aryloxy group, a heteroaryloxy group, an alkylthioether group, an arylthioether group, a heteroarylthioether group, a (meth)acryloyl group, an oxetanyl group, and a blocked isocyanate group. The blocked isocyanate group in the present specification is a group capable of generating an isocyanate group by heat, and preferred examples thereof include a group in which an isocyanate group is protected by reacting a blocking agent and an isocyanate group. Examples of the blocking agent include oxime compounds, lactam compounds, phenol compounds, alcohol compounds, amine compounds, active methylene compounds, pyrazole compounds, mercaptan compounds, imidazole compounds, and imide compounds. Examples of the blocking agent include compounds described in paragraphs 0115 to 0117 of JP2017-067930A, the contents of which are incorporated herein by reference. In addition, the blocked isocyanate group is preferably a group capable of generating an isocyanate group by heat of 90° C. to 260° C.

It is preferable that the polymer chain represented by P¹⁰ has at least one group (hereinafter, also referred to as a “functional group A”) selected from the group consisting of a (meth)acryloyl group, an oxetanyl group, a blocked isocyanate group, and a t-butyl group. The functional group A is more preferably at least one selected from the group consisting of a (meth)acryloyl group, an oxetanyl group, and a blocked isocyanate group. In a case where the polymer chain includes the functional group A, it is easy to form a film having excellent solvent resistance. In particular, the effects described above are remarkable in a case of including at least one group selected from a (meth)acryloyl group, an oxetanyl group, and a blocked isocyanate group. In addition, in a case where the functional group A has a t-butyl group, it is preferable that the resin composition includes a compound having an epoxy group or an oxetanyl group. In a case where the functional group A has a blocked isocyanate group, it is preferable that the resin composition includes a compound having a hydroxy group.

In addition, it is more preferable that the polymer chain represented by P¹⁰ is a polymer chain having a repeating unit including the above-described functional group A in the side chain. In addition, a proportion of the repeating unit including the above-described functional group A in the side chain with respect to total repeating units constituting P¹⁰ is preferably 5% by mass or more, more preferably 10% by mass or more, and still more preferably 20% by mass or more. The upper limit may be 100% by mass, and is preferably 90% by mass or less and more preferably 60% by mass or less.

In addition, it is also preferable that the polymer chain represented by P¹⁰ has a repeating unit including an acid group. Examples of the acid group include a carboxyl group, a phosphoric acid group, a sulfo group, and a phenolic hydroxy group. A proportion of the repeating unit including an acid group in the total repeating units constituting P¹⁰ is preferably 1% to 30% by mass, more preferably 2% by mass to 20% by mass, and still more preferably 3% to 10% by mass.

In the resin composition according to the embodiment of the present invention, as the resin having an acid group, a polyimine-based dispersant including a nitrogen atom in at least one of a main chain or a side chain can also be used. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

In the resin composition according to the embodiment of the present invention, as the resin having an acid group, a resin having a structure in which a plurality of polymer chains are bonded to a core portion can also be used. Examples of such a resin include dendrimers (including star polymers). In addition, specific examples of the dendrimer include polymer compounds C-1 to C-31 described in paragraph Nos. 0196 to 0209 of JP2013-043962A.

In the resin composition according to the embodiment of the present invention, as the resin having an acid group, a commercially available acidic dispersant can also be used. Specific examples thereof include DISPERBYK series (for example, DISPERBYK-111 and the like) manufactured by BYK Chemie, and Solsperse series manufactured by Lubrizol Corporation. Dispersing agents described in paragraph Nos. 0041 to 0130 of JP2014-130338A can also be used, the contents of which are incorporated herein by reference.

(Resin not Including Acid Group)

The resin composition according to the embodiment of the present invention can further contain a resin which does not include an acid group. Such a resin is not particularly limited, and examples thereof include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin.

In addition, as the resin which does not include an acid group, a resin having a basic group can also be used. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the resin having a basic group include a block copolymer (B) described in paragraph Nos. 0063 to 0112 of JP2014-219665A and a block copolymer A1 described in paragraph Nos. 0046 to 0076 of JP2018-156021A.

A content of the resin in the total solid content of the resin composition is preferably 5% to 40% by mass. The lower limit is preferably 10% by mass or more. The upper limit is preferably 30% by mass or less and more preferably 25% by mass or less.

A content of the resin having an acid group in the total solid content of the resin composition is preferably 5% to 40% by mass. The lower limit is preferably 10% by mass or more. The upper limit is preferably 30% by mass or less and more preferably 25% by mass or less.

In addition, the content of the resin having an acid group is preferably 20 to 120 parts by mass with respect to 100 parts by mass of the pigment. The lower limit is preferably 25 parts by mass or more and more preferably 30 parts by mass or more. The upper limit is preferably 110 parts by mass or less and more preferably 100 parts by mass or less.

In addition, the content of the resin having an acid group as the dispersant is preferably 10 to 60 parts by mass with respect to 100 parts by mass of the pigment. The lower limit is preferably 15 parts by mass or more and more preferably 20 parts by mass or more. The upper limit is preferably 50 parts by mass or less and more preferably 40 parts by mass or less.

<<Compound A>>

The resin composition according to the embodiment of the present invention includes a compound A which includes 3 or more basic groups in one molecule, has an amine value of 2.7 mmol/g or more, and has a molecular weight of 100 or more.

A molecular weight of the compound A is 100 or more, preferably 200 or more and more preferably 250 or more. The upper limit thereof is preferably 100000 or less, more preferably 50000 or less, still more preferably 10000 or less, and particularly preferably 2000 or less. With regard to the value of the molecular weight of the compound A, in a case where the molecular weight can be calculated from a structural formula, the molecular weight of the compound A is a value calculated from the structural formula. On the other hand, in a case where the molecular weight of the compound A cannot be calculated from the structural formula or is difficult to calculate, a value of a number-average molecular weight measured by a boiling point increase method is used. In addition, even in a case where the molecular weight of the compound A cannot be measured by the boiling point increase method or is difficult to be measured, a value of a number-average molecular weight measured by a viscosity method is used. In addition, in a case where the molecular weight of the compound A cannot be measured by the viscosity method or is difficult to be measured by the viscosity method, a value of a number-average molecular weight in terms of polystyrene through measurement by a gel permeation chromatography (GPC) method is used.

The amine value of the compound A is 2.7 mmol/g or more, preferably 5 mmol/g or more, more preferably 10 mmol/g or more, and still more preferably 15 mmol/g or more. The amine value of the compound A is calculated by a method described in Examples described later.

The number of basic groups included in the compound A is 3 or more, preferably 4 or more, more preferably 6 or more, and still more preferably 10 or more.

The basic group included in the compound A is preferably an amino group. In addition, the compound A is preferably a compound having a primary amino group, more preferably a compound including each of a primary amino group and a tertiary amino group, and still more preferably a compound including each of a primary amino group, a secondary amino group, and a tertiary amino group.

In addition, the amino group included in the compound A may be a cyclic amino group. The cyclic amino group may be an aliphatic cyclic amino group such as a piperidino group or an aromatic cyclic amino group such as a pyridyl group. The cyclic amino group is preferably a cyclic amino group having a 5-membered ring or 6-membered ring structure, more preferably a cyclic amino group having a 6-membered ring structure, and still more preferably an aliphatic cyclic amino group having a 6-membered ring structure. The cyclic amino group preferably has a hindered amine structure, and particularly has a 6-membered hindered amine structure. The hindered amine structure preferably has a substituent such as an alkyl group in two carbon atoms in the ring structure adjacent to the nitrogen atom of the cyclic amino group. Examples of the cyclic amino group having a hindered amine structure include a 1,2,2,6,6-pentamethylpiperidyl group, a 2,2,6,6-tetramethylpiperidyl group, a 1,2,6,6-trimethylpiperidyl group, a 2,6-dimethylpiperidyl group, a 1-methyl-2, 6-di(t-butyl)piperidyl group, a 2,6-di(t-butyl)piperidyl group, a 1,2,2,5,5-pentamethylpyrrolidyl group, and a 2,2,5,5-tetramethylpyrrolidyl group. Among these, a 1,2,2,6,6-pentamethylpiperidyl group or a 2,2,6,6-tetramethylpiperidyl group is preferable, and a 1,2,2,6,6-pentamethylpiperidyl group is more preferable.

From the reason that the storage stability of the resin composition can be further improved, the compound A is preferably a polyalkyleneimine. The polyalkyleneimine is a polymer obtained by ring-opening polymerization of alkyleneimine. The polyalkyleneimine is preferably a polymer having a branched structure including each of a primary amino group, a secondary amino group, and a tertiary amino group. The number of carbon atoms in the alkyleneimine is preferably 2 to 6, more preferably 2 to 4, still more preferably 2 or 3, and particularly preferably 2. Specific examples of the alkyleneimine include ethyleneimine, propyleneimine, 1,2-butyleneimine, and 2,3-butyleneimine, and ethyleneimine or propyleneimine is preferable and ethyleneimine is more preferable. The polyalkyleneimine is particularly preferably polyethyleneimine. In addition, the polyethyleneimine preferably includes the primary amino group in an amount of 10 mol % or more, more preferably includes the primary amino group in an amount of 20 mol % or more, and still more preferably includes the primary amino group in an amount of 30 mol % or more with respect to the total of the primary amino group, the secondary amino group, and the tertiary amino group. Examples of a commercially available product of the polyethyleneimine include EPOMIN SP-003, SP-006, SP-012, SP-018, SP-200, and P-1000 (all of which are manufactured by NIPPON SHOKUBAI CO., LTD.).

In addition, as the compound A, a compound having a cyclic amino group can also be used. Examples of such a compound include compounds having structures shown below. In addition, examples of a commercially available product thereof include ADEKA STAB LA-52, LA-57, LA-63P, and LA-68 (all of which are manufactured by ADEKA Corporation).

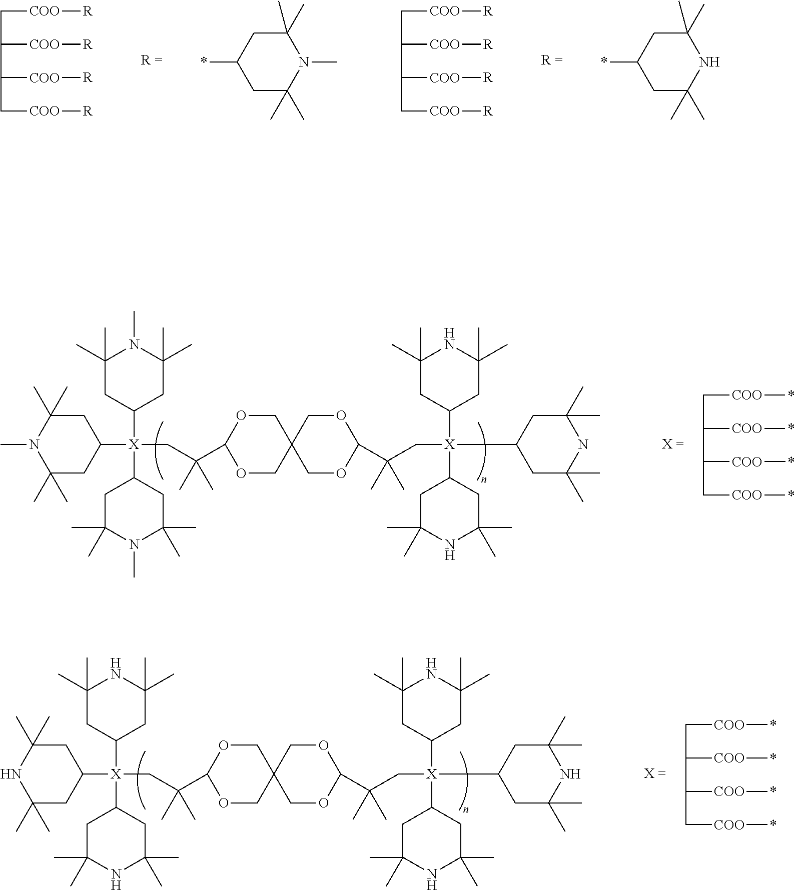

In addition, as the compound A, a resin having an amino group in a side chain can also be used. In addition, as the compound A, compounds having structures shown below can also be used.

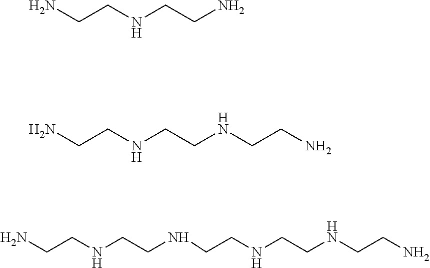 [SMILES: NCCNCCN ; NCCNCCNCCN ; NCCNCCNCCNCCNCCN]

A content of the compound A in the total solid content of the resin composition is preferably 0.1% to 5% by mass. The lower limit is preferably 0.2% by mass or more, more preferably 0.5% by mass or more, and still more preferably 1% by mass or more. The upper limit is preferably 4.5% by mass or less, more preferably 4% by mass or less, and still more preferably 3% by mass or less.

In addition, the content of the compound A is preferably 0.5 to 10 parts by mass with respect to 100 parts by mass of the pigment. The lower limit is preferably 0.6 parts by mass or more, more preferably 1 part by mass or more, and still more preferably 2 parts by mass or more. The upper limit is preferably 8 parts by mass or less, more preferably 7 parts by mass or less, and still more preferably 5 parts by mass or less.

In addition, the content of the compound A is preferably 0.5 to 50 parts by mass with respect to 100 parts by mass of the resin having an acid group. The lower limit is preferably 0.6 parts by mass or more, more preferably 1 part by mass or more, and still more preferably 3 parts by mass or more. The upper limit is preferably 45 parts by mass or less, more preferably 40 parts by mass or less, and still more preferably 30 parts by mass or less.

In addition, the content of the compound A is preferably 1 to 70 parts by mass with respect to 100 parts by mass of the resin having an acid group as the dispersant. The lower limit is preferably 2 parts by mass or more, more preferably 3 parts by mass or more, and still more preferably 5 parts by mass or more. The upper limit is preferably 65 parts by mass or less, more preferably 60 parts by mass or less, and still more preferably 50 parts by mass or less.

<<Pigment Derivative>>

The resin composition according to the embodiment of the present invention can contain a pigment derivative. According to this aspect, the storage stability of the resin composition can be further improved. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of max is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

A content of the pigment derivative is preferably 1 to 30 parts by mass and more preferably 3 to 20 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

In addition, the content of the pigment derivative is preferably 300 parts by mass or less, more preferably 200 parts by mass or less, and still more preferably 100 parts by mass or less with respect to 100 parts by mass of the compound A.

In addition, the total content of the pigment derivative and the compound A is preferably 0.5 to 30 parts by mass and more preferably 1 to 20 parts by mass with respect to 100 parts by mass of the pigment.

<<Polymerizable Compound>>

The resin composition according to the embodiment of the present invention preferably contains a polymerizable compound. As the polymerizable compound, a known compound which is cross-linkable by a radical, an acid, or heat can be used. In the present invention, the polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include compounds described in paragraph Nos. 0095 to 0108 of JP2009-288705A, paragraph Nos. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer Company Inc.) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., LTD.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

In addition, as the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxyl group, a sulfo group, and a phosphoric acid group, and a carboxyl group is preferable. Examples of the polymerizable compound having an acid group include succinic acid-modified dipentaerythritol penta(meth)acrylate. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

In addition, as the polymerizable compound, a compound having a caprolactone structure can also be used. Examples of a commercially available product of the polymerizable compound having a caprolactone structure include KAYARAD DPCA-20, DPCA-30, DPCA-60, and DPCA-120 (all manufactured by Nippon Kayaku Co., Ltd.).

In addition, as the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a 3-functional to 6-functional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330, which is a trifunctional (meth)acrylate having three isobutyleneoxy groups.

In addition, as the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

A content of the polymerizable compound in the total solid content of the resin composition is preferably 0.1% to 50% by mass. The lower limit is preferably 0.5% by mass or more, more preferably 1% by mass or more, and still more preferably 3% by mass or more. The upper limit is preferably 40% by mass or less, more preferably 30% by mass or less, and still more preferably 25% by mass or less. The polymerizable compound may be used singly or in a combination of two or more kinds thereof. In a case where two or more kinds thereof are used in combination, the total thereof is preferably within the above-described range.

<<Photopolymerization Initiator>>

The resin composition according to the embodiment of the present invention preferably includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, and peroxide initiators described in JP2019-167313A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, and compounds described in JP06636081B.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include a compound described in paragraph Nos. 0031 to 0047 of JP2013-114249A and paragraph Nos. 0008 to 0012 and 0070 to 0079 of JP2014-137466A, a compound described in paragraph Nos. 0007 to 0025 of JP4223071B, and ADEKAARKLS NCI-831 (manufactured by ADEKA Corporation).

An oxime compound having a benzofuran skeleton can also be used as the photopolymerization initiator. Specific examples thereof include 0E-01 to 0E-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

The oxime compound OX is preferably at least one selected from a compound represented by Formula (OX1) or a compound represented by Formula (OX2), and more preferably a compound represented by Formula (OX2).

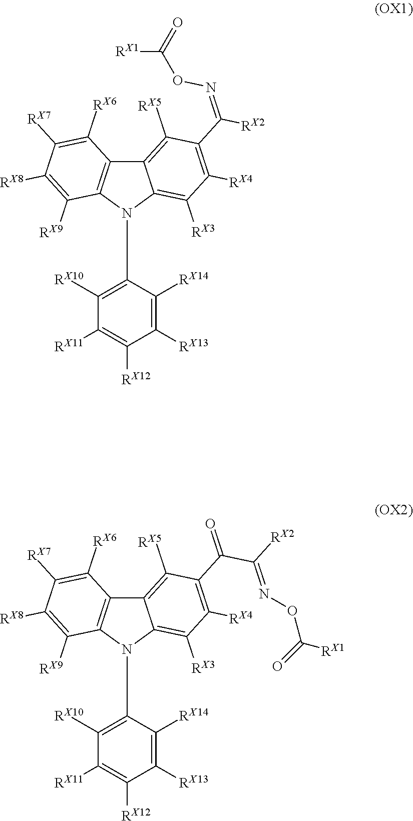

In the formula, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,

R^{X3} to R^{X14} each independently represent a hydrogen atom or a substituent, and

at least one of R^{X10}, . . . , or R^{X14} is an electron withdrawing group.

Examples of the electron withdrawing group include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable.

In the formulae, it is preferable that R^{X12} is an electron withdrawing group, and R^{X10}, R^{X11}, R^{X13}, and R^{X14} are hydrogen atoms.

Specific examples of the oxime compound OX include compounds described in paragraph Nos. 0083 to 0105 of JP4600600B.

Specific examples of the oxime compound which are preferably used in the present invention are shown below, but the present invention is not limited thereto.

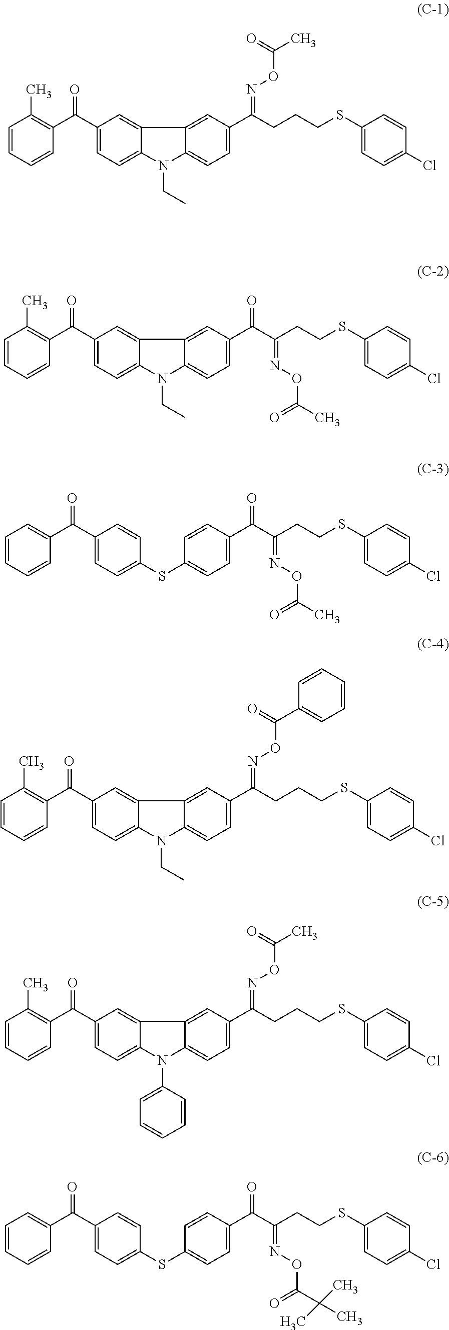 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc2c(c1)c1cc(C(=O)c3ccccc3C)ccc1n2-c1ccccc1 ; CC(C)(C)C(=O)O/N=C(\CCSc1ccc(Cl)cc1)C(=O)c1ccc(Sc2ccc(C(=O)c3ccccc3)cc2)cc1]

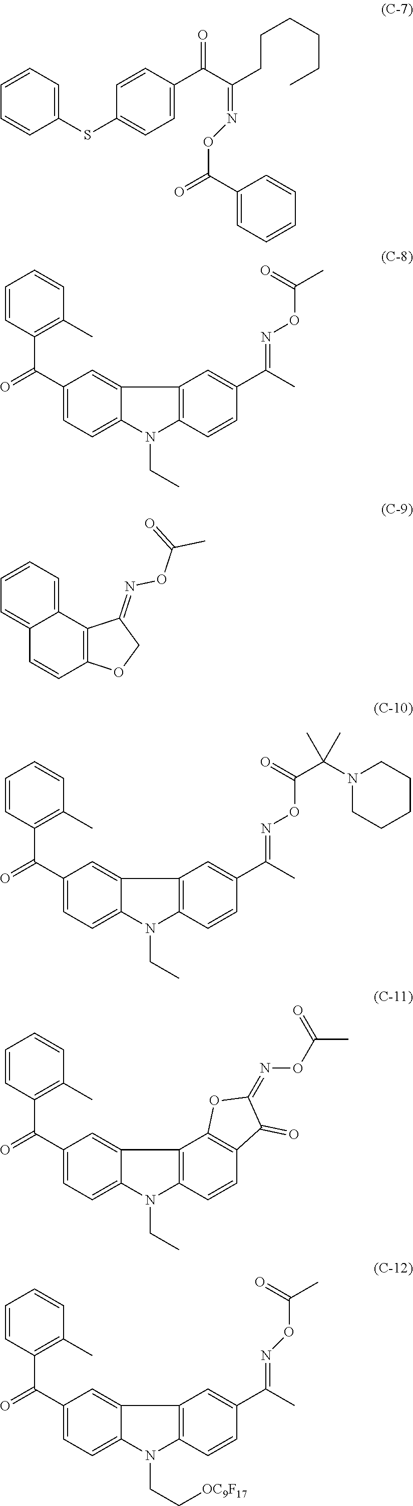

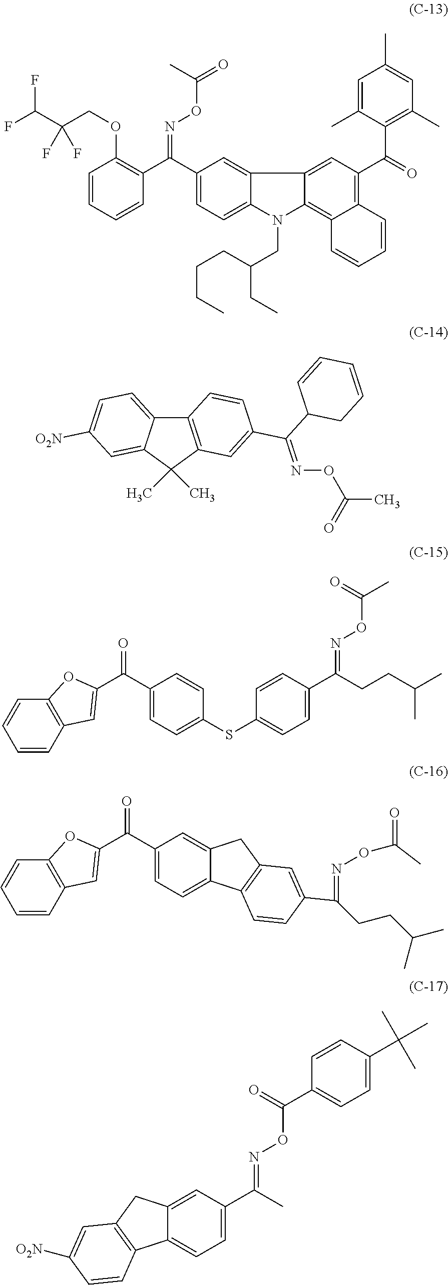 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(/c1ccc2c(c1)C(C)(C)c1cc([N+](=O)[O-])ccc1-2)C1C=CC=CC1 ; CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2 ; C/C(=N\OC(=O)c1ccc(C(C)(C)C)cc1)c1ccc2c(c1)Cc1cc([N+](=O)[O-])ccc1-2]

The oxime compound is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the resin composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the photopolymerization initiator in the total solid content of the resin composition is preferably 0.1% to 20% by mass. The lower limit is preferably 0.5% by mass or more and more preferably 1% by mass or more. The upper limit is preferably 10% by mass or less, more preferably 8% by mass or less, and still more preferably 6% by mass or less. The photopolymerization initiator may be used singly or in a combination of two or more kinds thereof. In a case where two or more kinds thereof are used in combination, the total thereof is preferably within the above-described range.

<<Compound Having Cyclic Ether Group>>

The resin composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). Examples of the epoxy compound include a compound having one or more epoxy groups in one molecule, and a compound having two or more epoxy groups in one molecule is preferable. The epoxy compound is preferably a compound having 1 to 100 epoxy groups in one molecule. The upper limit of the number of epoxy groups included in the epoxy compound may be, for example, 10 or less or 5 or less. The lower limit of the epoxy group included in the epoxy compound is preferably 2 or more. As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents thereof are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the compound having an epoxy group is preferably 200 to 100000 and more preferably 500 to 50000. The upper limit of the weight-average molecular weight is still more preferably 10000 or less, particularly preferably 5000 or less, and even more preferably 3000 or less.

As the epoxy compound, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

A content of the compound having a cyclic ether group in the total solid content of the resin composition is preferably 0.1% to 20% by mass. The lower limit is, for example, more preferably 0.5% by mass or more and still more preferably 1% by mass or more. The upper limit is, for example, more preferably 15% by mass or less and still more preferably 10% by mass or less. The compound having a cyclic ether group may be used singly or in a combination of two or more kinds thereof. In a case where two or more kinds thereof are used, the total amount thereof is preferably within the above-described range.

<<Curing Accelerator>>

The resin composition according to the embodiment of the present invention may include a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 0080 of JP2012-150180A, alkoxysilane compounds described in JP2011-253054A, compounds described in paragraph Nos. 0085 to 0092 of JP5765059B, and carboxyl group-containing epoxy curing agent described in JP2017-036379A. A content of the curing accelerator in the total solid content of the resin composition is preferably 0.3% to 8.9% by mass and more preferably 0.8% to 6.4% by mass.

<<Surfactant>>

The resin composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the resin composition, liquid characteristics (particularly, fluidity) are further improved, and liquid saving property can be further improved. In addition, it is possible to form a film with a small thickness unevenness.

The fluorine content in the fluorine-based surfactant is preferably 3% to 40% by mass, more preferably 5% to 30% by mass, and still more preferably 7% to 25% by mass. The fluorine-based surfactant in which the fluorine content is within the above-described range is effective in terms of the evenness of the thickness of the coating film or liquid saving property and the solubility of the surfactant in the resin composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, surfactants described in paragraph Nos. 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 710FM, 610FM, 601AD, 601ADH2, 602A, 215M, and 245F (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

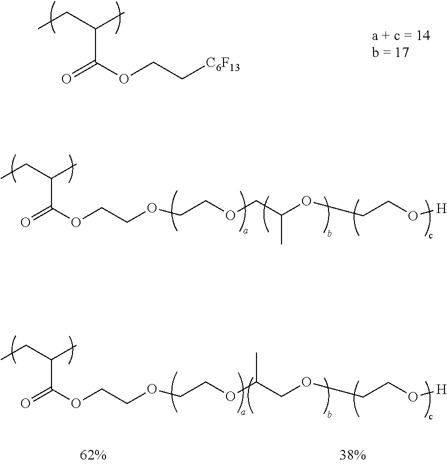

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

A content of the surfactant in the total solid content of the resin composition is preferably 0.001% by mass to 5.0% by mass and more preferably 0.005% to 3.0% by mass. The surfactant may be used singly or in a combination of two or more kinds thereof. In a case where two or more kinds thereof are used, the total amount thereof is preferably within the above-described range.

<<Solvent>>

The resin composition according to the embodiment of the present invention can contain a solvent. Basically, the type of the solvent is not particularly limited as long as it satisfies solubility of the respective components or coating properties of the composition. The solvent is preferably an organic solvent. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, and 3-methoxybutanol. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the resin composition is preferably 10% to 95% by mass. The upper limit is preferably 92.5% by mass or less and more preferably 90% by mass or less. From the viewpoint of coating properties, the lower limit is preferably 20% by mass or more, more preferably 50% by mass or more, still more preferably 70% by mass or more, even more preferably 75% by mass or more, and even still more preferably 80% by mass or more.

In addition, from the viewpoint of environmental regulation, it is preferable that the resin composition according to the embodiment of the present invention does not substantially contain environmentally regulated substances. In the present invention, the description “does not substantially contain environmentally regulated substances” means that the content of the environmentally regulated substances in the resin composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the resin composition, and may be incorporated into the resin composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, resin composition produced by mixing these compounds, or the like.

<<Silane Coupling Agent>>

The resin composition according to the embodiment of the present invention can contain a silane coupling agent. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

A content of the silane coupling agent in the total solid content of the resin composition is preferably 0.1% to 5% by mass. The upper limit is more preferably 3% by mass or less and still more preferably 2% by mass or less. The lower limit is more preferably 0.5% by mass or more and still more preferably 1% by mass or more. The silane coupling agent may be used singly or in a combination of two or more kinds thereof. In a case where two or more kinds thereof are used, the total amount thereof is preferably within the above-described range.

<<Ultraviolet Absorber>>

The resin composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the resin composition is preferably 0.01% to 10% by mass and more preferably 0.01% to 5% by mass. The ultraviolet absorber may be used singly or in a combination of two or more kinds thereof. In a case where two or more kinds thereof are used, the total amount thereof is preferably within the above-described range.

<<Antioxidant>>

The resin composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. In addition, as the antioxidant, compounds described in KR10-2019-0059371A can also be used. A content of the antioxidant in the total solid content of the resin composition is preferably 0.01% to 20% by mass and more preferably 0.3% to 15% by mass. The antioxidant may be used singly or in combination of two or more kinds thereof. In a case of using two or more kinds thereof, the total amount thereof is preferably within the above-described range.

<<Polymerization Inhibitor>>

The resin composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the resin composition is preferably 0.0001% to 5% by mass. The polymerization inhibitor may be used singly or in a combination of two or more kinds thereof. In a case of two or more kinds thereof, the total amount thereof is preferably within the above-described range.

<<Other Components>>

In the present invention, optionally, the resin composition may further contain a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the resin composition according to the embodiment of the present invention may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKAARKLS GPA-5001 (manufactured by ADEKA Corporation).

The resin composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the resin composition according to the embodiment of the present invention, the content of liberated metals which are not bonded to or coordinated with a pigment or the like is preferably 100 ppm or less, more preferably 50 ppm or less, and still more preferably 10 ppm or less, it is particularly preferable to not contain the liberated metals substantially. According to this aspect, effects such as stabilization of pigment dispersibility (restraint of aggregation), improvement of spectral characteristics due to improved dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the resin composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the resin composition include washing with ion exchange water, filtration, ultrafiltration, and purification with an ion exchange resin.

It is also preferable that the resin composition according to the embodiment of the present invention does not substantially include terephthalic acid ester. Here, the “does not substantially include” means that the content of terephthalic acid ester is 1000 mass ppb or less in the total amount of the resin composition, and it is more preferable to be 100 mass ppb or less and particularly preferable to be 0.

From the viewpoint of environmental regulation, the use of perfluoroalkyl sulfonic acid and a salt thereof and use of perfluoroalkyl carboxylic acid and a salt thereof may be restricted. In the resin composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the resin composition. The resin composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a resin composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The resin composition according to the embodiment of the present invention may include the perfluoroalkyl sulfonic acid and a salt thereof and the perfluoroalkyl carboxylic acid and a salt thereof within the maximum allowable range.

<<Storage Container>>

A storage container for the resin composition is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or resin compositions. Examples of such a container include the containers described in JP2015-123351A. In addition, for the purpose of preventing metal elution from the container interior wall, improving storage stability of the resin composition, and suppressing the alteration of components, it is also preferable that the container interior wall is formed of glass, stainless steel, or the like.

<Method for Preparing Resin Composition>

The resin composition according to the embodiment of the present invention can be prepared by mixing the above-described components with each other. In the preparation of the resin composition, all the components may be dissolved and/or dispersed at the same time in a solvent to prepare the resin composition, or the respective components may be appropriately left in two or more solutions or dispersion liquids and mixed to prepare the resin composition upon use (during coating), as desired.

In addition, in the preparation of the resin composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the resin composition, it is preferable that the resin composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPRO02, TPRO05, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Film>

The film according to the embodiment of the present invention is a film formed of the above-described resin composition according to the embodiment of the present invention. A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μM or more.

The film according to the embodiment of the present invention can be used for a color filter, a near-infrared transmitting filter, a near-infrared cut filter, a black matrix, a light-shielding film, and the like. The film according to the embodiment of the present invention can be preferably used as a colored pixel of a color filter. Examples of the colored pixel include a red pixel, a green pixel, a blue pixel, a magenta pixel, a cyan pixel, and a yellow pixel, and a green pixel or a cyan pixel is preferable and a green pixel is more preferable.

In a case where the film according to the embodiment of the present invention is used as a green pixel of a color filter, a wavelength at which a light transmittance of the film according to the embodiment of the present invention is 50% preferably exists in a wavelength range of 470 to 520 nm, more preferably exists in a wavelength range of 475 to 520 nm, and still more preferably exists in a wavelength range of 480 to 520 nm. Among these, the wavelength at which the light transmittance is 50% preferably exists in each wavelength range of 470 to 520 nm and wavelength range of 575 to 625 nm. In this aspect, a wavelength on a short wavelength side, at which the light transmittance is 50%, preferably exists in a wavelength range of 475 to 520 nm, and more preferably exists in a wavelength range of 480 to 520 nm. In addition, a wavelength on a long wavelength side, at which the light transmittance is 50%, preferably exists in a wavelength range of 580 to 620 nm, and more preferably exists in a wavelength range of 585 to 615 nm. A film having such spectral characteristics is preferably used as a green pixel.

In a case where the film according to the embodiment of the present invention is used as a near-infrared cut filter, the maximal absorption wavelength of the film according to the embodiment of the present invention is preferably in a wavelength range of 700 to 1800 nm, more preferably in a wavelength range of 700 to 1300 nm, and still more preferably in a wavelength range of 700 to 1100 nm. In addition, in the film, a transmittance of in the entire wavelength range of 400 to 650 nm is preferably 70% or more, more preferably 80% or more, and still more preferably 90% or more. In addition, the transmittance of the film at at least one point in a wavelength range of 700 to 1800 nm is preferably 20% or less. In addition, absorbance Aₘₐₓ/absorbance A₅₅₀, which is a ratio of an absorbance Aₘₐₓ at a maximal absorption wavelength to an absorbance A₅₅₀ at a wavelength of 550 nm, is preferably 20 to 500, more preferably 50 to 500, still more preferably 70 to 450, and particularly preferably 100 to 400.

In a case where the film according to the embodiment of the present invention is used as a near-infrared transmitting filter, it is preferable that the film according to the embodiment of the present invention has any one of the following spectral characteristics (i1) to (i5).

(i1): film in which the maximum value of a transmittance in a wavelength range of 400 to 640 nm is 20% or less (preferably 15% or less and more preferably 10% or less) and the minimum value of a transmittance in a wavelength range of 800 to 1500 nm is 70% or more (preferably 75% or more and more preferably 80% or more) A film having such spectral characteristics can shield light having a wavelength range of 400 to 640 nm, and can transmit light having a wavelength exceeding 750 nm.

(i2): film in which the maximum value of a transmittance in a wavelength range of 400 to 750 nm is 20% or less (preferably 15% or less and more preferably 10% or less) and the minimum value of a transmittance in a wavelength range of 900 to 1500 nm is 70% or more (preferably 75% or more and more preferably 80% or more) A film having such spectral characteristics can shield light having a wavelength range of 400 to 750 nm, and can transmit light having a wavelength exceeding 850 nm.

(i3): film in which the maximum value of a transmittance in a wavelength range of 400 to 830 nm is 20% or less (preferably 15% or less and more preferably 10% or less) and the minimum value of a transmittance in a wavelength range of 1000 to 1500 nm is 70% or more (preferably 75% or more and more preferably 80% or more) A film having such spectral characteristics can shield light having a wavelength range of 400 to 830 nm, and can transmit light having a wavelength exceeding 950 nm.

(i4): film in which the maximum value of a transmittance in a wavelength range of 400 to 950 nm is 20% or less (preferably 15% or less and more preferably 10% or less) and the minimum value of a transmittance in a wavelength range of 1100 to 1500 nm is 70% or more (preferably 75% or more and more preferably 80% or more) A film having such spectral characteristics can shield light having a wavelength range of 400 to 950 nm, and can transmit light having a wavelength exceeding 1050 nm.

(i5): film in which the maximum value of a transmittance in a wavelength range of 400 to 1050 nm is 20% or less (preferably 15% or less and more preferably 10% or less) and the minimum value of a transmittance in a wavelength range of 1200 to 1500 nm is 70% or more (preferably 75% or more and more preferably 80% or more) A film having such spectral characteristics can shield light having a wavelength range of 400 to 1050 nm, and can transmit light having a wavelength exceeding 1150 nm.

<Method for Producing Film>

Next, a method for producing the film according to the embodiment of the present invention will be described. The film according to the embodiment of the present invention can be formed through a step of applying the resin composition according to the embodiment of the present invention. The method for producing the film preferably further includes a step of forming a pattern (pixel). Examples of a method for forming the pattern (pixel) include a photolithography method and a dry etching method, and a photolithography method is preferable.

Pattern formation by the photolithography method preferably includes a step of forming a resin composition layer on a support using the resin composition according to the embodiment of the present invention, a step of exposing the resin composition layer in a patterned manner, and a step of removing a non-exposed portion of the resin composition layer by development to form a pattern (pixel). A step (pre-baking step) of baking the resin composition layer and a step (post-baking step) of baking the developed pattern (pixel) may be provided, optionally.

In the step of forming a resin composition layer, the resin composition layer is formed on a support using the resin composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the resin composition is good. The surface contact angle of the base layer can be adjusted by, for example, adding a surfactant.

As a method of applying the resin composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. The application method using an ink jet method is not particularly limited, and examples thereof include a method (in particular, pp. 115 to 133) described in “Extension of Use of Ink Jet—Infinite Possibilities in Patent-” (published in February, 2005, S.B. Research Co., Ltd.) and methods described in JP2003-262716A, JP2003-185831A, JP2003-261827A, JP2012-126830A, and JP2006-169325A. In addition, with regard to the method for applying the resin composition, reference can be made to the description in WO2017/030174A and WO2017/018419A, the contents of which are incorporated herein by reference.

The resin composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. Pre-baking can be performed using a hot plate, an oven, or the like.

Next, the resin composition layer is exposed in a patterned manner (exposing step). For example, the resin composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the resin composition layer is removed by development to form a pattern (pixel). The non-exposed portion of the resin composition layer can be removed by development using a developer. Thus, the resin composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to further improve residues removing properties, a step of shaking the developer off per 60 seconds and supplying a new developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkaline agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the resin composition layer after development while rotating the support on which the resin composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

Pattern formation by a dry etching method preferably includes a step of forming a resin composition layer on a support using the resin composition according to the embodiment of the present invention and curing the entire resin composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Optical Filter>

An optical filter according to an embodiment of the present invention has the above-described film according to the embodiment of the present invention. Examples of the type of the optical filter include a color filter, a near infrared cut filter, and a near infrared transmitting filter, and a color filter is preferable. The color filter preferably includes the film according to the embodiment of the present invention as a pixel thereof, more preferably includes the film according to the embodiment of the present invention as a colored pixel, and still more preferably includes the film according to the embodiment of the present invention as a green pixel.

In the optical filter, a thickness of the film according to the embodiment of the present invention can be appropriately adjusted depending on the purposes. The thickness of the film is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

A width of the pixel included in the optical filter is preferably 0.4 to 10.0 μm. The lower limit is preferably 0.4 μm or more, more preferably 0.5 μm or more, and still more preferably 0.6 μm or more. The upper limit is preferably 5.0 μm or less, more preferably 2.0 μm or less, still more preferably 1.0 μm or less, and even more preferably 0.8 μm or less. In addition, a Young's modulus of the pixel is preferably 0.5 to 20 GPa and more preferably 2.5 to 15 GPa.

Each pixel included in the optical filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured using an ultra-high resistance meter 5410 (manufactured by Advantest Corporation).

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition for forming a protective layer, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each pixel is embedded in a space partitioned in, for example, a lattice shape by a partition wall. The partition wall in this case preferably has a low refractive index for each pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Measurement Conditions of Weight-Average Molecular Weight and Number-Average Molecular Weight by Gel Permeation Chromatography Method>

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 μL (sample concentration: 0.1% by mass)

Device name: HLC-8220GPC manufactured by Tosoh Corporation

Detector: refractive index (RI) detector

Calibration curve base resin: polystyrene resin

<Measuring Method of Amine Value>

The amine value was calculated by the following method.

A measurement sample was dissolved in acetic acid, and the obtained solution was subjected to neutralization titration with a 0.1 mol/L perchloric acid/acetic acid solution using a potentiometric titrator (trade name: AT-510, manufactured by KYOTO ELECTRONICS MANUFACTURING CO., LTD.). An inflection point of a titration pH curve was set as a titration end point, and the amine value was calculated from the following expression.

B=Vs×0.1×f/w

B: amine value (mmol/g)

Vs: amount (mL) of the 0.1 mol/L perchloric acid/acetic acid solution used for the titration

f: titer of the 0.1 M perchloric acid/acetic acid solution

w: weight (g) of the measurement sample (expressed in terms of solid contents)

<Production of Dispersion Liquid>

(Dispersion Liquid Formulation 1)

A mixed solution of 14 parts by mass of a pigment, a total of 3.5 parts by mass of a specific compound, a pigment derivative, and a resin expressed in terms of solid contents, and 82.5 parts by mass of a solvent was mixed and dispersed for 3 hours using a beads mill (zirconia beads, 0.1 mm diameter) to prepare a dispersion liquid. Thereafter, using a high-pressure disperser NANO-3000-10 (manufactured by Nippon BEE Chemical Co., Ltd.) equipped with a pressure reducing mechanism, the dispersion liquid was dispersed under a pressure of 2000 kg/cm² at a flow rate of 500 g/min. The dispersion treatment was repeated up to a total of 10 times to obtain a dispersion liquid. Materials shown in the tables below were used as the pigment, the pigment derivative, the resin, the specific compound, and the solvent. In addition, the mixing ratio of the pigment derivative, the resin, and the specific compound in the tables below is a value expressed in terms of solid contents.

(Dispersion Liquid Formulation 2)

A mixed solution of 14 parts by mass of a pigment, a total of 4.9 parts by mass of a specific compound, a pigment derivative, and a resin expressed in terms of solid contents, and 81.1 parts by mass of a solvent was mixed and dispersed for 3 hours using a beads mill (zirconia beads, 0.1 mm diameter) to prepare a dispersion liquid. Thereafter, using a high-pressure disperser NANO-3000-10 (manufactured by Nippon BEE Chemical Co., Ltd.) equipped with a pressure reducing mechanism, the dispersion liquid was dispersed under a pressure of 2000 kg/cm² at a flow rate of 500 g/min. The dispersion treatment was repeated up to a total of 10 times to obtain a dispersion liquid. Materials shown in the tables below were used as the pigment, the pigment derivative, the resin, the specific compound, and the solvent. In addition, the mixing ratio of the pigment derivative, the resin, and the specific compound in the tables below is a value expressed in terms of solid contents.

TABLE 1

| | | [symbol] | | | | | | [symbol] | | | | | | [symbol] | | | |
|---|---|---|---|---|---|---|---|---|---|---|---|---|---|---|---|---|---|
| | | Type | | | [symbol] | | | Type | | | [symbol] | | | Type | | [symbol] | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Dispersion | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |

[symbol]

indicates data missing or illegible when filed

TABLE 2

| | | [symbol] | | | | | | [symbol] | | | | | | [symbol] | | | |
|---|---|---|---|---|---|---|---|---|---|---|---|---|---|---|---|---|---|
| | | Type | | | [symbol] | | | Type | | | [symbol] | | | Type | | [symbol] | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Dispersion | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |

[symbol]

indicates data missing or illegible when filed

TABLE 3

| | | [symbol] | | | | | | [symbol] | | | | | | [symbol] | | | |
|---|---|---|---|---|---|---|---|---|---|---|---|---|---|---|---|---|---|
| | | Type | | | [symbol] | | | Type | | | [symbol] | | | Type | | [symbol] | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Dispersion | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |

[symbol]

indicates data missing or illegible when filed

TABLE 4

| | | [symbol] | | | | | | [symbol] | | | | | | [symbol] | | | |
|---|---|---|---|---|---|---|---|---|---|---|---|---|---|---|---|---|---|
| | | Type | | | [symbol] | | | Type | | | [symbol] | | | Type | | [symbol] | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Dispersion | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |

[symbol]

indicates data missing or illegible when filed

TABLE 5

| | | [symbol] | | | | | | [symbol] | | | | | | [symbol] | | | |
|---|---|---|---|---|---|---|---|---|---|---|---|---|---|---|---|---|---|
| | | Type | | | [symbol] | | | Type | | | [symbol] | | | Type | | [symbol] | |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| Dispersion | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |
| Dispersion | | | | | | | | | | | | | | | | | |
| liquid [symbol] | | | | | | | | | | | | | | | | | |

[symbol]

indicates data missing or illegible when filed

TABLE 6

| | | | [symbol] | | | | | | |
|---|---|---|---|---|---|---|---|---|---|
| | | [symbol] | Type | | | [symbol] | | | [symbol] |
| | [symbol] | Type | [symbol] | [symbol] | [symbol] | [symbol] | [symbol] | [symbol] | Type |
| Com- | [symbol] | [symbol] | [symbol] | [symbol] | [symbol] | [symbol] | [symbol] | [symbol] | [symbol] |
| parative | | | | | | | | | |
| [symbol] | | | | | | | | | |
| Com- | [symbol] | [symbol] | [symbol] | [symbol] | [symbol] | [symbol] | [symbol] | [symbol] | [symbol] |
| parative | | | | | | | | | |
| [symbol] | | | | | | | | | |
| Com- | [symbol] | [symbol] | [symbol] | [symbol] | [symbol] | [symbol] | [symbol] | [symbol] | [symbol] |
| parative | | | | | | | | | |
| [symbol] | | | | | | | | | |

[symbol]

indicates data missing or illegible when filed

The details of the materials indicated by the abbreviations in the tables showing the formulation of the dispersion liquids described above are as follows.

(Pigment)

P-1: C. I. Pigment Green 7 (halogenated copper phthalocyanine pigment, green pigment)

P-2: C. I. Pigment Green 36 (halogenated copper phthalocyanine pigment, green pigment)

P-3: C. I. Pigment Green 58 (halogenated zinc phthalocyanine pigment, green pigment)

P-4: C. I. Pigment Green 59 (halogenated zinc phthalocyanine pigment, green pigment)

P-5: C. I. Pigment Green 63 (halogenated aluminum phthalocyanine pigment, green pigment)

P-6: C. I. Pigment Yellow 129 (azomethine copper complex, yellow pigment)

P-7: C. I. Pigment Yellow 138 (yellow pigment)

P-8: C. I. Pigment Yellow 139 (yellow pigment)

P-9: C. I. Pigment Yellow 150 (azonickel metal complex pigment, yellow pigment)

P-10: C. I. Pigment Yellow 185 (yellow pigment)

P-11: C. I. Pigment Yellow 215 (yellow pigment)

P-12: C. I. Pigment Yellow 231 (yellow pigment)

P-13: C. I. Pigment Yellow 233 (yellow pigment)

P-14: C. I. Pigment Red 122 (red pigment)

P-15: C. I. Pigment Red 177 (red pigment)

P-16: C. I. Pigment Red 254 (red pigment)

P-17: C. I. Pigment Red 264 (red pigment)

P-18: C. I. Pigment Red 269 (red pigment)

P-19: C. I. Pigment Red 272 (red pigment)

P-20: C. I. Pigment Blue 15:4 (copper phthalocyanine pigment, blue pigment)

P-21: C. I. Pigment Blue 15:6 (copper phthalocyanine pigment, blue pigment)

P-22: C. I. Pigment Blue 16 (blue pigment)

P-23: C. I. Pigment Violet 23 (violet pigment)

P-24: TiO₂ (pigment containing titanium atom, white pigment)

P-25: TiON (pigment containing titanium atom, black pigment)

P-26: compound having the following structure (near-infrared absorbing pigment)

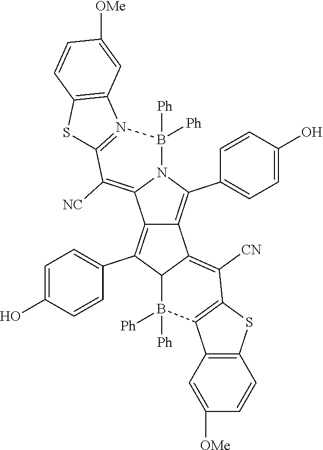

P-27: compound having the following structure (near-infrared absorbing pigment)

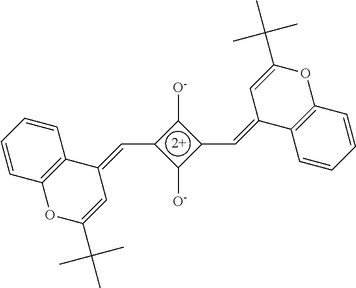

(Specific Compound)

A-1: polyethyleneimine (EPOMIN SP-003, manufactured by NIPPON SHOKUBAI CO., LTD.)

A-2: polyethyleneimine (EPOMIN SP-006, manufactured by NIPPON SHOKUBAI CO., LTD.)

A-3: polyethyleneimine (EPOMIN SP-012, manufactured by NIPPON SHOKUBAI CO., LTD.)

A-4: polyethyleneimine (EPOMIN SP-018, manufactured by NIPPON SHOKUBAI CO., LTD.)

A-5: polyethyleneimine (EPOMIN SP-200, manufactured by NIPPON SHOKUBAI CO., LTD.)

A-6: polyethyleneimine (EPOMIN P-1000, manufactured by NIPPON SHOKUBAI CO., LTD.)

A-7: compound having the following structure (hindered amine compound, ADEKA STAB LA-52, manufactured by ADEKA Corporation)

A-8: compound having the following structure (hindered amine compound, ADEKA STAB LA-57, manufactured by ADEKA Corporation)

A-9: compound having the following structure (hindered amine compound, ADEKA STAB LA-63P, manufactured by ADEKA Corporation)

A-10: compound having the following structure (hindered amine compound, ADEKA STAB LA-68, manufactured by ADEKA Corporation)

A-11: compound having the following structure

A-12: compound having the following structure

A-13: compound having the following structure

A-14: compound having the following structure

AN-1: compound having the following structure

AN-2: compound having the following structure

AN-3: resin having the following structure (the numerical value described together with the main chain indicates a mass ratio)

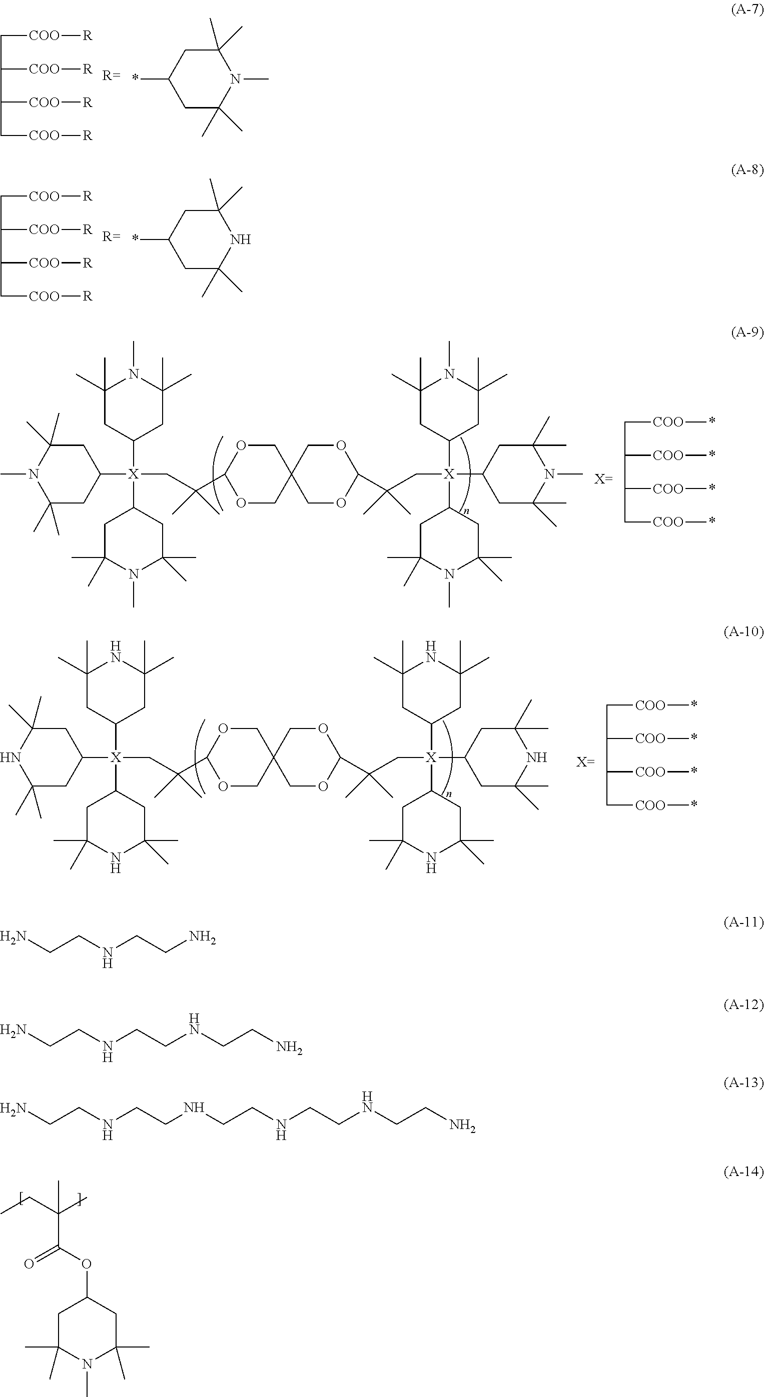

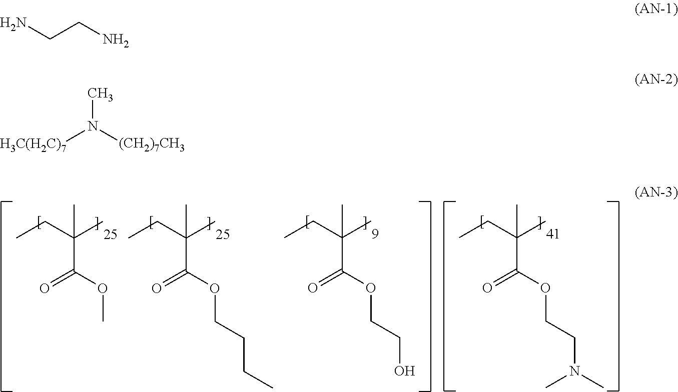

The following table shows physical property values of the specific compounds A-1 to A-14 and AN-1 to AN-3. The physical property values of the specific compounds A-1 to A-6 are catalog values. Among these, the values of molecular weights of the specific compounds A-1 to A-5 are values of number-average molecular weights (catalog values) measured by the boiling point increase method. In addition, the value of molecular weight of the specific compound A-6 is a value of number-average molecular weight (catalog value) measured by the viscosity method. In addition, the values of molecular weights of the specific compounds A-9, A-10, A-14, and AN-3 are values of number-average molecular weights measured by the GPC method. The values of the molecular weights of the specific compounds A-7, A-8, A-11, A-12, A-13, AN-1, and AN-2 are calculated values from the structural formulae.

TABLE 7

| | | | | Amino group ratio (%) | | |
|---|---|---|---|---|---|---|
| | Amine | | Number | Primary | Secondary | Tertiary |
| | value | Molecular | of groups | amino | amino | amino |
| Type | (mmol/g) | weight | amino | group | group | group |
| A-1 | 21 | 300 | 6 | 45 | 35 | 20 |
| A-2 | 20 | 600 | 12 | 35 | 35 | 30 |
| A-3 | 19 | 1200 | 23 | 35 | 35 | 30 |
| A-4 | 19 | 1800 | 34 | 35 | 35 | 30 |
| A-5 | 18 | 10000 | 180 | 35 | 35 | 30 |
| A-6 | 18 | 70000 | 1260 | 25 | 50 | 25 |
| A-7 | 4.7 | 847 | 4 | 0 | 0 | 100 |
| A-8 | 5.4 | 791 | 4 | 0 | 100 | 0 |
| A-9 | 3.5 | 2000 | 7 | 0 | 0 | 100 |
| A-10 | 3.6 | 1900 | 7 | 0 | 100 | 0 |
| A-11 | 29.1 | 103.2 | 3 | 67 | 33 | 0 |
| A-12 | 27.4 | 146.2 | 4 | 50 | 50 | 0 |
| A-13 | 25.8 | 232.4 | 6 | 33 | 67 | 0 |
| A-14 | 3.7 | 3000 | 11 | 0 | 0 | 100 |
| AN-1 | 33.3 | 60.1 | 2 | 100 | 0 | 0 |
| AN-2 | 3.9 | 255.5 | 1 | 0 | 0 | 100 |
| AN-3 | 2.5 | 8000 | 20 | 0 | 0 | 100 |

(Pigment Derivative)

Syn-1: compound having the following structure (amine value: 2.2 mmol/g, compound having two amino groups)

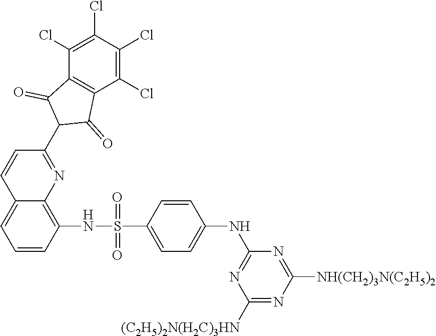

Syn-2: compound having the following structure (amine value: 2.9 mmol/g, compound having two amino groups)

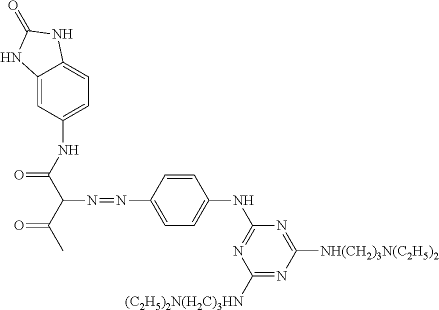

Syn-3: compound having the following structure (amine value: 2.6 mmol/g, compound having two amino groups)

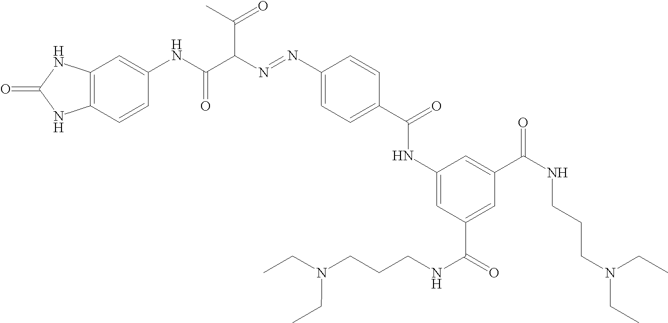 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Resin)

B-1: 30% by mass of PGMEA solution of a resin B-1 synthesized by the following method

50 parts by mass of methyl methacrylate, 30 parts by mass of n-butyl methacrylate, 20 parts by mass of t-butyl methacrylate, and 45.4 parts by mass of propylene glycol monomethyl ether acetate (PGMEA) were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated to obtain a resin B-1 (resin having an acid group) having the following structure, in which an acid value was 43 mgKOH/g and a weight-average molecular weight was 9000.

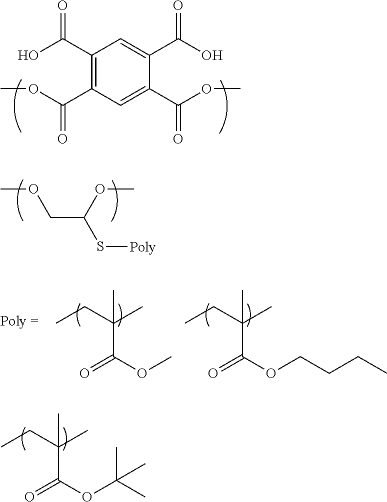

B-2: 30% by mass of PGMEA solution of a resin B-2 synthesized by the following method

6.0 parts by mass of 3-mercapto-1,2-propanediol, 9.5 parts by mass of pyromellitic acid anhydride, 62 parts by mass of PGMEA, and 0.2 parts by mass of 1,8-diazabicyclo-[5.4.0]-7-undecene were charged into a reaction container, and the atmosphere gas was replaced with nitrogen gas. The inside of the reaction container was heated to 100° C., and the mixture was reacted for 7 hours. After confirming by acid value measurement that 98% or more of the acid anhydride was half-esterified, the temperature in the system was lowered to 70° C., 53.5 parts by mass of PGMEA solution in which 65 parts by mass of methyl methacrylate, 5.0 parts by mass of ethyl acrylate, 15 parts by mass of t-butyl acrylate, 5.0 parts by mass of methacrylic acid, 10 parts by mass of hydroxyethyl methacrylate, and 0.1 parts by mass of 2,2′-azobisisobutyronitrile were dissolved was added thereto, and the mixture was reacted for 10 hours. It was confirmed by solid content measurement that 95% of the polymerization was proceeded, and the reaction was terminated to obtain a resin B-2 (resin having an acid group) having the following structure, in which an acid value was 70.5 mgKOH/g and a weight-average molecular weight was 10000.

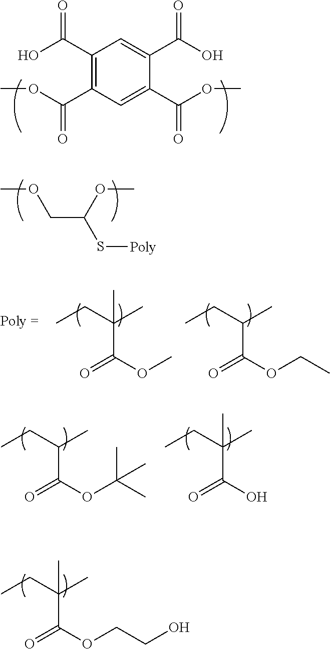

B-3: 30% by mass of PGMEA solution of a resin B-3 synthesized by the following method

A resin B-3 (resin having an acid group) having the following structure, in which an acid value was 43 mgKOH/g and a weight-average molecular weight was 9000, was obtained in the same manner as in the synthesis of the resin B-1, except that 20 parts by mass of t-butyl methacrylate was changed to 20 parts by mass of (3-ethyloxetan-3-yl)methyl methacrylate.

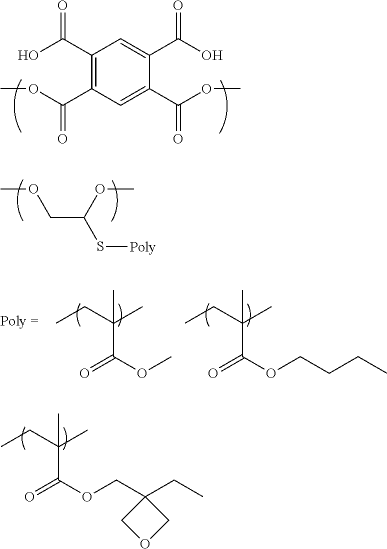

B-4: 30% by mass of PGMEA solution of a resin B-4 synthesized by the following method

108 parts by mass of 1-thioglycerol, 174 parts by mass of pyromellitic acid anhydride, 650 parts by mass of methoxypropyl acetate, and 0.2 parts by mass of monobutyltin oxide as a catalyst were charged into a reaction container, the atmosphere gas was replaced with nitrogen gas, and the mixture was reacted at 120° C. for 5 hours (first step). It was confirmed by acid value measurement that 95% or more of the acid anhydride was half-esterified. Next, 160 parts by mass of the compound obtained in the first step expressed in terms of solid contents, 200 parts by mass of 2-hydroxypropyl methacrylate, 200 parts by mass of ethyl acrylate, 150 parts by mass of t-butyl acrylate, 200 parts by mass of 2-methoxyethyl acrylate, 200 parts by mass of methyl acrylate, 50 parts by mass of methacrylic acid, and 663 parts by mass of PGMEA were charged to a reaction container, the inside of the reaction container was heated to 80° C., 1.2 parts by mass of 2,2′-azobis(2,4-dimethylvaleronitrile) was added thereto, and the mixture was reacted for 12 hours (second step). It was confirmed by solid content measurement that 95% thereof was reacted. Finally, 500 parts by mass of PGMEA solution of 50% by mass of the compound obtained in the second step, 27.0 parts by mass of 2-methacryloyloxyethyl isocyanate (MOI), 0.1 parts by mass of hydroquinone were charged to a reaction container, the reaction was performed until the disappearance of the peak of 2270 cm⁻¹ based on the isocyanate group was confirmed (third step). After confirming the disappearance of the peak, the reaction solution was cooled to obtain a resin B-4 (resin having an acid group) having the following structure, in which an acid value was 68 mgKOH/g, an ethylenically unsaturated bond group value was 0.62 mmol/g, and a weight-average molecular weight was 13000.

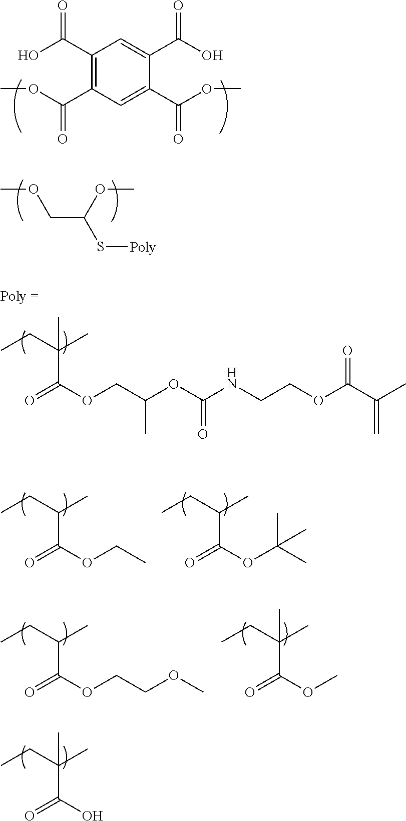

B-5: 30% by mass PGMEA solution of a resin having the following structure (the numerical value described together with the main chain indicates a molar ratio, and the numerical value described together with the side chain indicates the number of repeating units; resin having an acid group; weight-average molecular weight: 16000, acid value: 67 mgKOH/g)

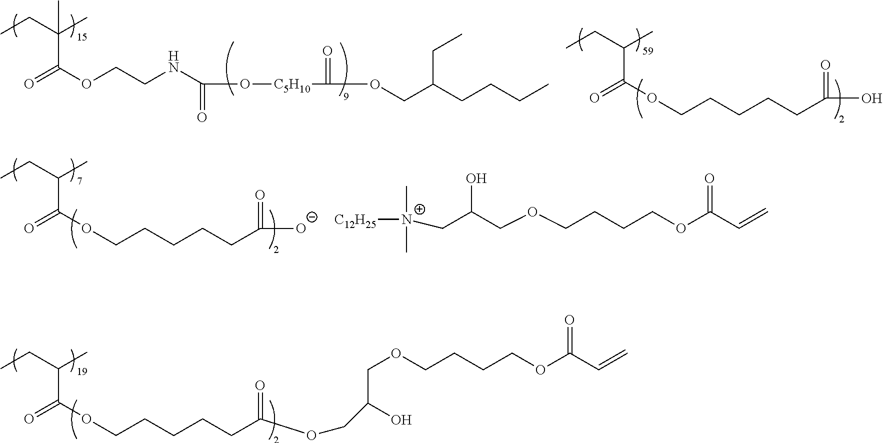

B-6: 30% by mass PGMEA solution of a resin having the following structure (the numerical value described together with the main chain indicates a molar ratio, and the numerical value described together with the side chain indicates the number of repeating units; resin having an acid group; weight-average molecular weight: 24000, acid value: 52.5 mgKOH/g)

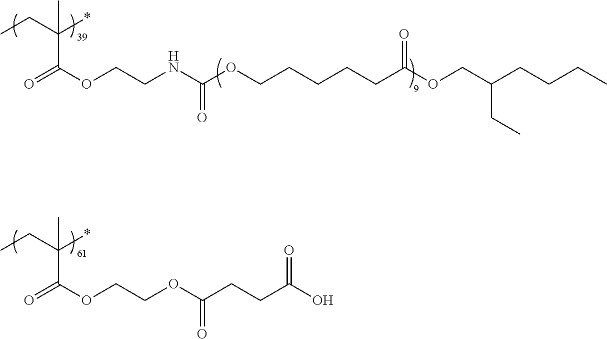

B-7: 30% by mass PGMEA solution of a resin having the following structure (the numerical value described together with the main chain indicates a molar ratio, and the numerical value described together with the side chain indicates the number of repeating units; resin having an acid group; weight-average molecular weight: 18000, acid value: 82.1 mgKOH/g)

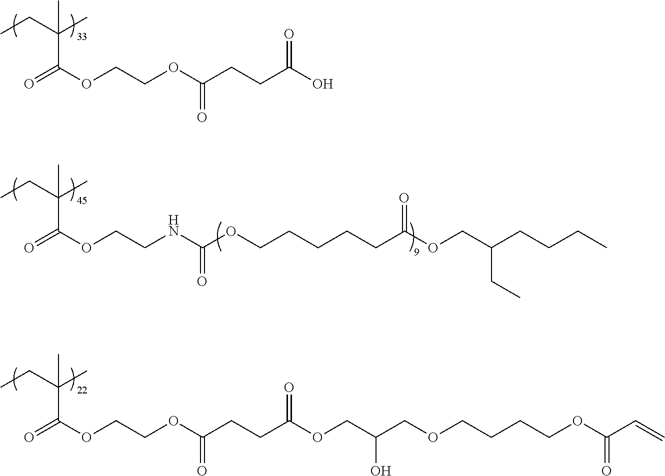

B-8: solution prepared by adding PGMEA to DISPERBYK-111 (manufactured by BYK Chemie, resin having an acid group) to adjust the non-volatile content (concentration of solid contents) to 30% by mass

(Solvent)

S-1: propylene glycol monomethyl ether acetate (PGMEA)

S-2: propylene glycol monomethyl ether (PGME)

S-3: cyclohexanone

S-4: cyclopentanone

S-5: 2-heptanone

S-6: γ-butyrolactone

<Production of Resin Composition>

Each material was mixed at a proportion of Formulations 1 to 5 shown below, and the obtained mixture was filtered through a nylon filter (manufactured by Pall Corporation) having a pore size of 0.45 μm to produce each resin composition. In the following tables, the value of the content of the pigment in the total solid content of the resin composition is shown in the column of “Pigment concentration”.

(Formulation 1)

| Dispersion liquid described in table | 51.4 | parts by mass |
|---|---|---|
| Polymerizable monomer described in table | 3.6 | parts by mass |
| Resin described in table | 12.5 parts by mass (blending amount | |
| | in 30% by mass of PGMEA solution) | |
| Photopolymerization initiator described in table | 0.9 | parts by mass |
| Surfactant described in table | 0.02 | parts by mass |
| Polymerization inhibitor described in table | 0.0002 | parts by mass |
| Solvent described in table | 31.5 | parts by mass |

(Formulation 2)

| Dispersion liquid described in table | 64.3 | parts by mass |
|---|---|---|
| Polymerizable monomer described in table | 2.7 | parts by mass |
| Resin described in table | 7.4 parts by mass (blending amount | |
| | in 30% by mass of PGMEA solution) | |
| Photopolymerization initiator described in table | 0.9 | parts by mass |
| Surfactant described in table | 0.02 | parts by mass |
| Polymerization inhibitor described in table | 0.0002 | parts by mass |
| Solvent described in table | 24.7 | parts by mass |

(Formulation 3)

| Dispersion liquid described in table | 77.1 | parts by mass |
|---|---|---|
| Polymerizable monomer described in table | 0.9 | parts by mass |
| Resin described in table | 6.5 parts by mass (blending amount | |
| | in 30% by mass of PGMEA solution) | |
| Photopolymerization initiator described in table | 0.5 | parts by mass |
| Surfactant described in table | 0.02 | parts by mass |
| Polymerization inhibitor described in table | 0.0002 | parts by mass |
| Solvent described in table | 14.9 | parts by mass |

(Formulation 4)

| Dispersion liquid described in table | 83.6 | parts by mass |
|---|---|---|
| Polymerizable monomer described in table | 0.9 | parts by mass |
| Resin described in table | 5.2 parts by mass (blending amount | |
| | in 30% by mass of PGMEA solution) | |
| Photopolymerization initiator described in table | 0.5 | parts by mass |
| Surfactant described in table | 0.02 | parts by mass |
| Polymerization inhibitor described in table | 0.0002 | parts by mass |
| Solvent described in table | 9.8 | parts by mass |

(Formulation 5)

| Dispersion liquid described in table | 77.1 | parts by mass |
|---|---|---|
| Polymerizable monomer described in table | 0.9 | parts by mass |
| Resin described in table | 5.3 parts by mass (blending amount | |
| | in 30% by mass of PGMEA solution) | |
| Photopolymerization initiator described in table | 0.5 | parts by mass |
| 30% by mass cyclopentanone solution of specific | 1.2 | parts by mass |
| compound described in table | | |
| Surfactant described in table | 0.02 | parts by mass |
| Polymerization inhibitor described in table | 0.0002 | parts by mass |
| Solvent described in table | 14.9 | parts by mass |

TABLE 8

| | Pigment | | | Poly- | | Photopoly- | | Poly- | |
|---|---|---|---|---|---|---|---|---|---|
| | concentration | Type of | Dispersion | merizable | | merization | Sur- | merization | |
| | (% by mass) | formulation | liquid | monomer | Resin | initiator | factant | inhibitor | Solvent |
| Example 1 | 40 | Formulation 1 | Dispersion | M-1 | B-1 | I-1 | W-1 | In-1 | S-1 |
| | | | liquid G-1 | | | | | | |
| Example 2 | 40 | Formulation 1 | Dispersion | M-1 | B-1 | I-1 | W-1 | In-1 | S-1 |
| | | | liquid G-2 | | | | | | |
| Example 3 | 40 | Formulation 1 | Dispersion | M-1 | B-1 | I-1 | W-1 | In-1 | S-1 |
| | | | liquid G-3 | | | | | | |
| Example 4 | 40 | Formulation 1 | Dispersion | M-1 | B-1 | I-1 | W-1 | In-1 | S-1 |
| | | | liquid G-4 | | | | | | |
| Example 5 | 40 | Formulation 1 | Dispersion | M-1 | B-1 | I-1 | W-1 | In-1 | S-1 |
| | | | liquid G-5 | | | | | | |
| Example 6 | 40 | Formulation 1 | Dispersion | M-1 | B-1 | I-1 | W-1 | In-1 | S-1 |
| | | | liquid Y-1 | | | | | | |
| Example 7 | 40 | Formulation 1 | Dispersion | M-1 | B-1 | I-1 | W-1 | In-1 | S-1 |
| | | | liquid Y-2 | | | | | | |
| Example 8 | 40 | Formulation 1 | Dispersion | M-1 | B-1 | I-1 | W-1 | In-1 | S-1 |
| | | | liquid Y-3 | | | | | | |
| Example 9 | 40 | Formulation 1 | Dispersion | M-1 | B-1 | I-1 | W-1 | In-1 | S-1 |
| | | | liquid Y-4 | | | | | | |
| Example 10 | 40 | Formulation 1 | Dispersion | M-1 | B-1 | I-1 | W-1 | In-1 | S-1 |
| | | | liquid Y-5 | | | | | | |
| Example 11 | 40 | Formulation 1 | Dispersion | M-1 | B-1 | I-1 | W-1 | In-1 | S-1 |
| | | | liquid Y-6 | | | | | | |
| Example 12 | 40 | Formulation 1 | Dispersion | M-1 | B-1 | I-1 | W-1 | In-1 | S-1 |
| | | | liquid Y-7 | | | | | | |
| Example 13 | 40 | Formulation 1 | Dispersion | M-1 | B-1 | I-1 | W-1 | In-1 | S-1 |
| | | | liquid Y-8 | | | | | | |
| Example 14 | 40 | Formulation 1 | Dispersion | M-1 | B-1 | I-1 | W-1 | In-1 | S-1 |
| | | | liquid R-1 | | | | | | |
| Example 15 | 40 | Formulation 1 | Dispersion | M-1 | B-1 | I-1 | W-1 | In-1 | S-1 |
| | | | liquid R-2 | | | | | | |
| Example 16 | 40 | Formulation 1 | Dispersion | M-1 | B-1 | I-1 | W-1 | In-1 | S-1 |
| | | | liquid R-3 | | | | | | |
| Example 17 | 40 | Formulation 1 | Dispersion | M-1 | B-1 | I-1 | W-1 | In-1 | S-1 |
| | | | liquid R-4 | | | | | | |
| Example 18 | 40 | Formulation 1 | Dispersion | M-1 | B-1 | I-1 | W-1 | In-1 | S-1 |
| | | | liquid R-5 | | | | | | |
| Example 19 | 40 | Formulation 1 | Dispersion | M-1 | B-1 | I-1 | W-1 | In-1 | S-1 |
| | | | liquid R-6 | | | | | | |
| Example 20 | 40 | Formulation 1 | Dispersion | M-1 | B-1 | I-1 | W-1 | In-1 | S-1 |
| | | | liquid B-1 | | | | | | |
| Example 21 | 40 | Formulation 1 | Dispersion | M-1 | B-1 | I-1 | W-1 | In-1 | S-1 |
| | | | liquid B-2 | | | | | | |
| Example 22 | 40 | Formulation 1 | Dispersion | M-1 | B-1 | I-1 | W-1 | In-1 | S-1 |
| | | | liquid B-3 | | | | | | |
| Example 23 | 40 | Formulation 1 | Dispersion | M-1 | B-1 | I-1 | W-1 | In-1 | S-1 |
| | | | liquid V-1 | | | | | | |
| Example 24 | 40 | Formulation 1 | Dispersion | M-1 | B-1 | I-1 | W-1 | In-1 | S-1 |
| | | | liquid W-1 | | | | | | |
| Example 25 | 40 | Formulation 1 | Dispersion | M-1 | B-1 | I-1 | W-1 | In-1 | S-1 |
| | | | liquid K-1 | | | | | | |
| Example 26 | 40 | Formulation 1 | Dispersion | M-1 | B-1 | I-1 | W-1 | In-1 | S-1 |
| | | | liquid S-1 | | | | | | |
| Example 27 | 40 | Formulation 1 | Dispersion | M-1 | B-1 | I-1 | W-1 | In-1 | S-1 |
| | | | liquid S-2 | | | | | | |
| Example 28 | 40 | Formulation 1 | Dispersion | M-1 | B-1 | I-1 | W-1 | In-1 | S-1 |
| | | | liquid G-6 | | | | | | |
| Example 29 | 40 | Formulation 1 | Dispersion | M-1 | B-1 | I-1 | W-1 | In-1 | S-1 |
| | | | liquid G-7 | | | | | | |
| Example 30 | 40 | Formulation 1 | Dispersion | M-1 | B-1 | I-1 | W-1 | In-1 | S-1 |
| | | | liquid G-8 | | | | | | |

TABLE 9

| | Pigment | | | Poly- | | Photopoly- | | Poly- | |
|---|---|---|---|---|---|---|---|---|---|
| | concentration | Type of | | merizable | | merization | Sur- | merization | |
| | (% by mass) | formulation | Dispersion liquid | monomer | Resin | initiator | factant | inhibitor | Solvent |
| Example 31 | 40 | Formulation 1 | Dispersion liquid G-9 | M-1 | B-1 | I-1 | W-1 | In-1 | S-1 |
| Example 32 | 40 | Formulation 1 | Dispersion liquid G-10 | M-1 | B-1 | I-1 | W-1 | In-1 | S-1 |
| Example 33 | 40 | Formulation 1 | Dispersion liquid G-11 | M-1 | B-1 | I-1 | W-1 | In-1 | S-1 |
| Example 34 | 40 | Formulation 1 | Dispersion liquid G-12 | M-1 | B-1 | I-1 | W-1 | In-1 | S-1 |
| Example 35 | 40 | Formulation 1 | Dispersion liquid G-13 | M-1 | B-1 | I-1 | W-1 | In-1 | S-1 |
| Example 36 | 40 | Formulation 1 | Dispersion liquid G-14 | M-1 | B-1 | I-1 | W-1 | In-1 | S-1 |
| Example 37 | 40 | Formulation 1 | Dispersion liquid G-15 | M-1 | B-1 | I-1 | W-1 | In-1 | S-1 |
| Example 38 | 40 | Formulation 1 | Dispersion liquid G-16 | M-1 | B-1 | I-1 | W-1 | In-1 | S-1 |
| Example 39 | 40 | Formulation 1 | Dispersion liquid G-17 | M-1 | B-1 | I-1 | W-1 | In-1 | S-1 |
| Example 40 | 40 | Formulation 1 | Dispersion liquid G-18 | M-1 | B-1 | I-1 | W-1 | In-1 | S-1 |
| Example 41 | 40 | Formulation 1 | Dispersion liquid G-19 | M-1 | B-1 | I-1 | W-1 | In-1 | S-1 |
| Example 42 | 40 | Formulation 1 | Dispersion liquid G-20 | M-1 | B-1 | I-1 | W-1 | In-1 | S-1 |
| Example 43 | 40 | Formulation 1 | Dispersion liquid G-21 | M-1 | B-1 | I-1 | W-1 | In-1 | S-1 |
| Example 44 | 40 | Formulation 1 | Dispersion liquid G-22 | M-1 | B-1 | I-1 | W-1 | In-1 | S-1 |
| Example 45 | 40 | Formulation 1 | Dispersion liquid G-23 | M-1 | B-1 | I-1 | W-1 | In-1 | S-1 |
| Example 46 | 40 | Formulation 1 | Dispersion liquid G-24 | M-1 | B-1 | I-1 | W-1 | In-1 | S-1 |
| Example 47 | 40 | Formulation 1 | Dispersion liquid G-25 | M-1 | B-1 | I-1 | W-1 | In-1 | S-1 |
| Example 48 | 40 | Formulation 1 | Dispersion liquid G-26 | M-1 | B-1 | I-1 | W-1 | In-1 | S-1 |
| Example 49 | 40 | Formulation 1 | Dispersion liquid G-27 | M-1 | B-1 | I-1 | W-1 | In-1 | S-1 |
| Example 50 | 40 | Formulation 1 | Dispersion liquid G-28 | M-1 | B-1 | I-1 | W-1 | In-1 | S-1 |
| Example 51 | 40 | Formulation 1 | Dispersion liquid G-29 | M-1 | B-1 | I-1 | W-1 | In-1 | S-1 |
| Example 52 | 40 | Formulation 1 | Dispersion liquid G-30 | M-1 | B-1 | I-1 | W-1 | In-1 | S-1 |
| Example 53 | 40 | Formulation 1 | Dispersion liquid G-31 | M-1 | B-1 | I-1 | W-1 | In-1 | S-1 |
| Example 54 | 40 | Formulation 1 | Dispersion liquid G-32 | M-1 | B-1 | I-1 | W-1 | In-1 | S-1 |
| Example 55 | 40 | Formulation 1 | Dispersion liquid G-33 | M-1 | B-1 | I-1 | W-1 | In-1 | S-1 |
| Example 56 | 40 | Formulation 1 | Dispersion liquid G-34 | M-1 | B-1 | I-1 | W-1 | In-1 | S-1 |
| Example 57 | 40 | Formulation 1 | Dispersion liquid G-35 | M-1 | B-1 | I-1 | W-1 | In-1 | S-1 |
| Example 58 | 40 | Formulation 1 | Dispersion liquid G-36 | M-1 | B-1 | I-1 | W-1 | In-1 | S-1 |
| Example 59 | 40 | Formulation 1 | Dispersion liquid G-37 | M-1 | B-1 | I-1 | W-1 | In-1 | S-1 |
| Example 60 | 40 | Formulation 1 | Dispersion liquid G-38 | M-1 | B-1 | I-1 | W-1 | In-1 | S-1 |

TABLE 10

| | Pigment | | | Poly- | | Photopoly- | | Poly- | |
|---|---|---|---|---|---|---|---|---|---|
| | concentration | Type of | | merizable | | merization | Sur- | merization | |
| | (% by mass) | formulation | Dispersion liquid | monomer | Resin | initiator | factant | inhibitor | Solvent |
| Example 61 | 40 | Formulation 1 | Dispersion liquid G-39 | M-1 | B-1 | I-1 | W-1 | In-1 | S-1 |
| Example 62 | 40 | Formulation 1 | Dispersion liquid G-40 | M-1 | B-1 | I-1 | W-1 | In-1 | S-1 |
| Example 63 | 40 | Formulation 1 | Dispersion liquid G-41 | M-1 | B-1 | I-1 | W-1 | In-1 | S-1 |
| Example 64 | 40 | Formulation 1 | Dispersion liquid G-42 | M-1 | B-1 | I-1 | W-1 | In-1 | S-1 |
| Example 65 | 40 | Formulation 1 | Dispersion liquid G-43 | M-1 | B-1 | I-1 | W-1 | In-1 | S-1 |
| Example 66 | 40 | Formulation 1 | Dispersion liquid G-44 | M-1 | B-1 | I-1 | W-1 | In-1 | S-1 |
| Example 67 | 40 | Formulation 1 | Dispersion liquid G-45 | M-1 | B-1 | I-1 | W-1 | In-1 | S-1 |
| Example 68 | 40 | Formulation 1 | Dispersion liquid G-46 | M-1 | B-1 | I-1 | W-1 | In-1 | S-1 |
| Example 69 | 40 | Formulation 1 | Dispersion liquid G-47 | M-1 | B-1 | I-1 | W-1 | In-1 | S-1 |
| Example 70 | 40 | Formulation 1 | Dispersion liquid G-48 | M-1 | B-1 | I-1 | W-1 | In-1 | S-1 |
| Example 71 | 40 | Formulation 1 | Dispersion liquid G-49 | M-1 | B-1 | I-1 | W-1 | In-1 | S-1 |
| Example 72 | 40 | Formulation 1 | Dispersion liquid G-50 | M-1 | B-1 | I-1 | W-1 | In-1 | S-1 |
| Example 73 | 40 | Formulation 1 | Dispersion liquid G-51 | M-1 | B-1 | I-1 | W-1 | In-1 | S-1 |
| Example 74 | 40 | Formulation 1 | Dispersion liquid G-52 | M-1 | B-1 | I-1 | W-1 | In-1 | S-1 |
| Example 75 | 40 | Formulation 1 | Dispersion liquid G-53 | M-1 | B-1 | I-1 | W-1 | In-1 | S-1 |
| Example 76 | 40 | Formulation 1 | Dispersion liquid G-54 | M-1 | B-1 | I-1 | W-1 | In-1 | S-1 |
| Example 77 | 40 | Formulation 1 | Dispersion liquid R-7 | M-1 | B-1 | I-1 | W-1 | In-1 | S-1 |
| Example 78 | 40 | Formulation 1 | Dispersion liquid R-8 | M-1 | B-1 | I-1 | W-1 | In-1 | S-1 |
| Example 79 | 40 | Formulation 1 | Dispersion liquid R-9 | M-1 | B-1 | I-1 | W-1 | In-1 | S-1 |
| Example 80 | 40 | Formulation 1 | Dispersion liquid R-10 | M-1 | B-1 | I-1 | W-1 | In-1 | S-1 |
| Example 81 | 40 | Formulation 1 | Dispersion liquid R-11 | M-1 | B-1 | I-1 | W-1 | In-1 | S-1 |
| Example 82 | 40 | Formulation 1 | Dispersion liquid R-12 | M-1 | B-1 | I-1 | W-1 | In-1 | S-1 |
| Example 83 | 40 | Formulation 1 | Dispersion liquid B-4 | M-1 | B-1 | I-1 | W-1 | In-1 | S-1 |
| Example 84 | 40 | Formulation 1 | Dispersion liquid B-5 | M-1 | B-1 | I-1 | W-1 | In-1 | S-1 |
| Example 85 | 40 | Formulation 1 | Dispersion liquid B-6 | M-1 | B-1 | I-1 | W-1 | In-1 | S-1 |

TABLE 11

| | | | [symbol] | | | | [symbol] | | | | |
|---|---|---|---|---|---|---|---|---|---|---|---|
| | Pigment | | Type | | [symbol] | | Type | | [symbol] | | |
| | concentration | Type of | [symbol] | [symbol] | [symbol] | [symbol] | [symbol] | [symbol] | [symbol] | [symbol] | |
| | (% by mass) | [symbol] | [symbol] | [symbol] | [symbol] | [symbol] | [symbol] | [symbol] | [symbol] | [symbol] | [symbol] |
| Example | [symbol] | [symbol] | [symbol] | [symbol] | [symbol] | [symbol] | [symbol] | [symbol] | [symbol] | [symbol] | [symbol] |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |

[symbol]

indicates data missing or illegible when filed

TABLE 12

| | [symbol] | | | | | | | |
|---|---|---|---|---|---|---|---|---|
| | Type | | [symbol] | | [symbol] | | | |
| | [symbol] | [symbol] | [symbol] | [symbol] | compound | [symbol] | [symbol] | Solvent |
| Example | [symbol] | [symbol] | [symbol] | [symbol] | [symbol] | [symbol] | [symbol] | [symbol] |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |
| Example | | | | | | | | |
| [symbol] | | | | | | | | |

[symbol]

indicates data missing or illegible when filed

TABLE 13

| | | | Pigment dispersion [symbol] | | | | [symbol] | | | | |
|---|---|---|---|---|---|---|---|---|---|---|---|
| | Pigment | | Type | | [symbol] | | Type | | [symbol] | | |
| | concentration | Type of | Dispersion | Dispersion | Dispersion | Dispersion | [symbol] | [symbol] | [symbol] | [symbol] | |
| | (% by mass) | [symbol] | liquid [symbol] | liquid [symbol] | liquid [symbol] | liquid [symbol] | [symbol] | [symbol] | [symbol] | [symbol] | [symbol] |
| Example | [symbol] | [symbol] | [symbol] | [symbol] | [symbol] | [symbol] | [symbol] | [symbol] | [symbol] | [symbol] | [symbol] |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |
| Example | | | | | | | | | | | |
| [symbol] | | | | | | | | | | | |

[symbol]

indicates data missing or illegible when filed

TABLE 14

| | Photopolymerization initiator | | | | | | | |
|---|---|---|---|---|---|---|---|---|
| | Type | | Mixing ratio (mass ratio) | | | | | |
| | Photopoly- | Photopoly- | Photopoly- | Photopoly- | | | Poly- | |
| | merization | merization | merization | merization | Specific | Sur- | merization | |
| | initiator 1 | initiator 2 | initiator 1 | initiator 2 | compound | factant | inhibitor | Solvent |
| Example | I-1 | — | 1 | 0 | — | W-1 | In-1 | S-1 |
| 106 | | | | | | | | |
| Example | I-1 | — | 1 | 0 | — | W-1 | In-1 | S-1 |
| 107 | | | | | | | | |
| Example | I-1 | — | 1 | 0 | — | W-1 | In-1 | S-1 |
| 108 | | | | | | | | |
| Example | I-1 | — | 1 | 0 | — | W-1 | In-1 | S-1 |
| 109 | | | | | | | | |
| Example | I-1 | — | 1 | 0 | — | W-1 | In-1 | S-1 |
| 110 | | | | | | | | |
| Example | I-1 | — | 1 | 0 | — | W-1 | In-1 | S-1 |
| 111 | | | | | | | | |
| Example | I-1 | — | 1 | 0 | — | W-1 | In-1 | S-1 |
| 112 | | | | | | | | |
| Example | I-1 | — | 1 | 0 | — | W-1 | In-1 | S-1 |
| 113 | | | | | | | | |
| Example | I-1 | — | 1 | 0 | — | W-1 | In-1 | S-1 |
| 114 | | | | | | | | |
| Example | I-1 | — | 1 | 0 | — | W-1 | In-1 | S-1 |
| 115 | | | | | | | | |
| Example | I-1 | — | 1 | 0 | — | W-1 | In-1 | S-1 |
| 116 | | | | | | | | |
| Example | I-1 | — | 1 | 0 | — | W-1 | In-1 | S-1 |
| 117 | | | | | | | | |
| Example | I-1 | — | 1 | 0 | — | W-1 | In-1 | S-1 |
| 118 | | | | | | | | |
| Example | I-1 | — | 1 | 0 | — | W-1 | In-1 | S-1 |
| 119 | | | | | | | | |
| Example | I-1 | — | 1 | 0 | — | W-1 | In-1 | S-1 |
| 120 | | | | | | | | |
| Example | I-2 | — | 1 | 0 | — | W-1 | In-1 | S-1 |
| 121 | | | | | | | | |
| Example | I-3 | — | 1 | 0 | — | W-1 | In-1 | S-1 |
| 122 | | | | | | | | |
| Example | I-4 | — | 1 | 0 | — | W-1 | In-1 | S-1 |
| 123 | | | | | | | | |
| Example | I-5 | — | 1 | 0 | — | W-1 | In-1 | S-1 |
| 124 | | | | | | | | |
| Example | I-1 | I-5 | 0.5 | 0.5 | — | W-1 | In-1 | S-1 |
| 125 | | | | | | | | |
| Example | I-2 | I-5 | 0.5 | 0.5 | — | W-1 | In-1 | S-1 |
| 126 | | | | | | | | |
| Example | I-3 | I-5 | 0.5 | 0.5 | — | W-1 | In-1 | S-1 |
| 127 | | | | | | | | |
| Example | I-4 | I-5 | 0.5 | 0.5 | — | W-1 | In-1 | S-1 |
| 128 | | | | | | | | |

[TABLE 15

| | Pigment | | | Poly- | | Photopoly- | | Poly- | |
|---|---|---|---|---|---|---|---|---|---|
| | concentration | Type of | Dispersion | merizable | | merization | Sur- | merization | |
| | (% by mass) | formulation | liquid | monomer | Resin | initiator | factant | inhibitor | Solvent |
| Com- | 40 | Formu- | Comparative | M-1 | B-1 | I-1 | W-1 | In-1 | S-1 |
| parative | | lation 1 | dispersion | | | | | | |
| Example 1 | | | liquid G-1 | | | | | | |
| Com- | 40 | Formu- | Comparative | M-1 | B-1 | I-1 | W-1 | In-1 | S-1 |
| parative | | lation 1 | dispersion | | | | | | |
| Example 2 | | | liquid G-2 | | | | | | |
| Com- | 40 | Formu- | Comparative | M-1 | B-1 | I-1 | W-1 | In-1 | S-1 |
| parative | | lation 1 | dispersion | | | | | | |
| Example 3 | | | liquid G-3 | | | | | | |

Among the materials indicated by the abbreviations in the tables showing the formulation of the resin compositions described above, details other than the dispersion liquid are as follows. As the dispersion liquid, the above-described dispersion liquid was used.

(Polymerizable Monomer)

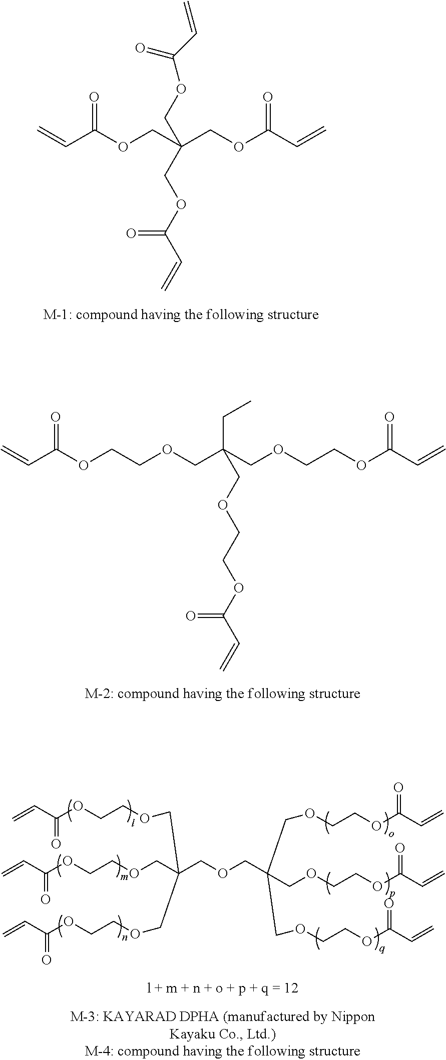

(Photopolymerization Initiator)

I-1: Irgacure OXE01 (manufactured by BASF SE, oxime compound)

I-2: Irgacure OXE02 (manufactured by BASF SE, oxime compound)

I-3, 1-4: compounds having the following structures

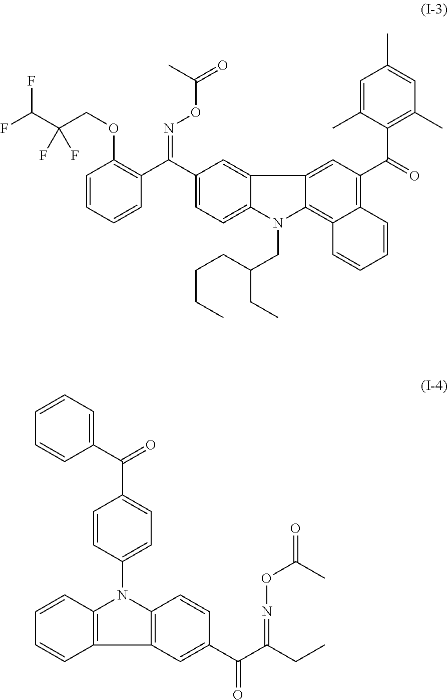 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCC(=NOC(C)=O)C(=O)c1ccc2c(c1)c1ccccc1n2-c1ccc(C(=O)c2ccccc2)cc1]

I-5: Omnirad 379 (manufactured by IGM Resins B.V., α-aminoketone compound)

(Resin)

B-1 to B-8: resins B-1 to B-8 described above (30% by mass of PGMEA solution)

B-9: 30% by mass PGMEA solution of a resin having the following structure (the numerical value described together with the main chain indicates a molar ratio; resin having an acid group; weight-average molecular weight: 11000, acid value: 69.2 mgKOH/g)

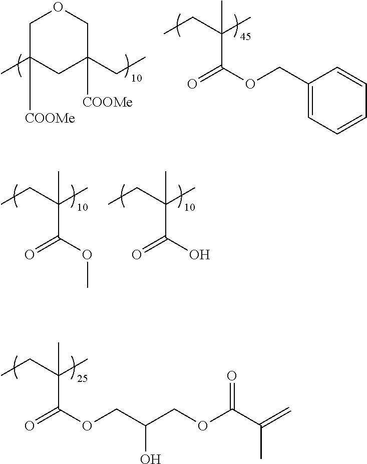

B-10: 30% by mass PGMEA solution of a resin having the following structure (the numerical value described together with the main chain indicates a molar ratio; resin having an acid group; weight-average molecular weight: 21000)

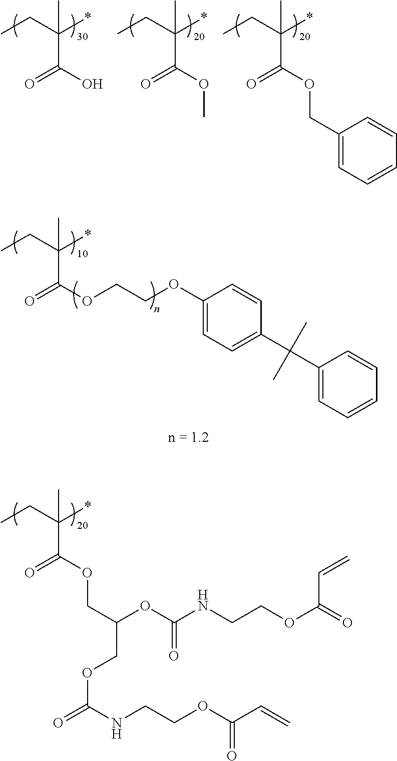

B-11: 30% by mass PGMEA solution of a resin having the following structure (the numerical value described together with the main chain indicates a molar ratio; resin having an acid group; weight-average molecular weight: 30000, acid value: 112.8 mgKOH/g)

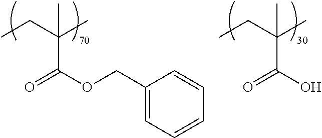

B-12: 30% by mass PGMEA solution of a resin having the following structure (the numerical value described together with the main chain indicates a molar ratio; resin having an acid group; weight-average molecular weight: 14000, acid value: 79.3 mgKOH/g)

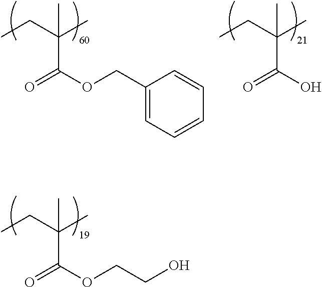

(Specific Compound)

A-2: specific compound A-2 described above

(Surfactant)

W-1: compound having the following structure (weight-average molecular weight: 14000; in the formula, “%” representing the proportion of a repeating unit is mol %)

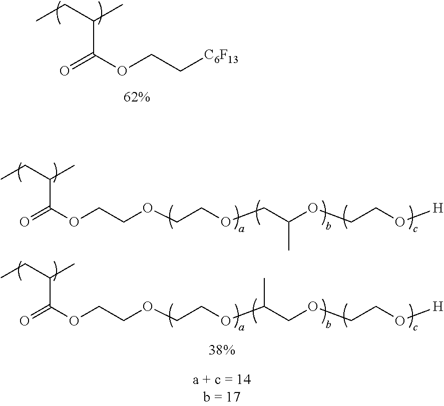

(Polymerization Inhibitor)

In-1: p-methoxyphenol

(Solvent)

S-1: propylene glycol monomethyl ether acetate (PGMEA)

<Evaluation of Storage Stability>

An initial viscosity (V0) of the resin composition immediately after the production was measured with “RE-85L” manufactured by TOKI SANGYO CO., LTD. After measuring the initial viscosity (V0), the resin composition was allowed to stand at a temperature of 4° C. for 6 months, and then a viscosity (V1) after standing was measured. A viscosity fluctuation rate (%) of the resin composition after standing was calculated from the following expression, and the storage stability was evaluated according to the following standard. The viscosity of the resin composition was measured in a state in which the temperature was adjusted to 25° C.

Viscosity fluctuation rate (%)=((Viscosity(V1) after standing−Initial viscosity (V0))/Initial viscosity (V0))×100

5: viscosity fluctuation rate was less than 5%.

4: viscosity fluctuation rate was 5% or more and less than 10%.

3: viscosity fluctuation rate was 10% or more and less than 30%.

2: viscosity fluctuation rate was 30% or more and less than 100%.

1: viscosity fluctuation rate was 100% or more.

<Evaluation of Foreign Matter>

A composition for a base layer was applied to a silicon wafer having a diameter of 8 inch (=20.32 cm) by a spin coating method. Next, the composition was heated using a hot plate at 100° C. for 2 minutes and was further heated using a hot plate at 230° C. for 2 minutes. As a result, a base layer having a film thickness of 10 nm was formed. The composition for a base layer will be described later.

Next, each of the resin compositions of Examples 1 to 128 and Comparative Examples 1 to 3 was applied to the silicon wafer on which the base layer had been formed by a spin coating method so that a film thickness after film formation was 0.4 μm, and the resin composition was heated using a hot plate at 100° C. for 2 minutes. Next, using an i-ray stepper exposure device FPA-3000 i5+(manufactured by Canon Inc.), the coating film was exposed through a mask having a 1.0 μm island pattern at an exposure amount of 150 mJ/cm². Next, the coating film was stored for 30 minutes in an environment with a temperature of 23° C. and a humidity of 50%, and puddle development was performed at 23° C. for 60 seconds using a 0.3% by mass of tetramethylammonium hydroxide (TMAH) aqueous solution. Thereafter, the coating film was rinsed with a spin shower, washed with pure water, and heated using a hot plate at 220° C. for 5 minutes to form a pixel of an island pattern.

After performing a constant temperature test (holding for 2000 hours in an environment with a temperature of 150° C.) on the silicon wafer on which the island pattern had been formed, 30 points on the surface of the silicon wafer were observed with an optical microscope to confirm the presence or absence of foreign matters in the film. The evaluation results are shown in the tables below.

5: no foreign matter was observed after the constant temperature test.

4: 1 to 3 points where the foreign matters were observed after the constant temperature test.

3: 4 to 10 points where the foreign matters were observed after the constant temperature test.

2: 11 to 20 points where the foreign matters were observed after the constant temperature test.

1: 21 to 30 points where the foreign matters were observed after the constant temperature test.

<Evaluation of Spectroscopy>

A composition for a base layer was applied to a glass wafer having a diameter of 8 inch (=20.32 cm) by a spin coating method. Next, the composition was heated using a hot plate at 100° C. for 2 minutes and was further heated using a hot plate at 230° C. for 2 minutes. As a result, a base layer having a film thickness of 10 nm was formed. The composition for a base layer will be described later.

Next, each of the resin compositions of Examples 1 to 23, 28 to 85, and 88 to 128, and Comparative Examples 1 to 3 was applied to the glass wafer on which the base layer had been formed by a spin coating method so that a film thickness after film formation was 0.4 μm, and the resin composition was heated using a hot plate at 100° C. for 2 minutes. Next, using an i-ray stepper exposure device FPA-3000 i5+(manufactured by Canon Inc.), the coating film was exposed through a mask having a 2 cm island pattern at an exposure amount of 150 mJ/cm². Next, the glass wafer was stored for 30 minutes in an environment with a temperature of 23° C. and a humidity of 50%, and puddle development was performed at 23° C. for 60 seconds using a 0.3% by mass of tetramethylammonium hydroxide (TMAH) aqueous solution. Thereafter, the coating film was rinsed with a spin shower, washed with pure water, and heated using a hot plate at 220° C. for 5 minutes to form a pattern for spectral evaluation.

With the glass wafer on which the pattern for spectral measurement had been formed, the variation rate of transmittance of light having a wavelength of 400 to 700 nm before and after the constant temperature test (holding for 2000 hours in an environment with a temperature of 150° C.) was obtained.

Variation rate of transmittance (%)=(|T2−T1|/T1)×100

T1 is an integrated value of the transmittance of light having a wavelength of 400 to 700 nm before the constant temperature test, and T2 is an integrated value of the transmittance of light having a wavelength of 400 to 700 nm after the constant temperature test.

5: variation rate of transmittance was less than 3%.

4: variation rate of transmittance was 3% or more and less than 5%.

3: variation rate of transmittance was 5% or more and less than 10%.

2: variation rate of transmittance was 10% or more and less than 20%.

1: variation rate of transmittance was 20% or more.

(Composition for Base Layer)

The composition for a base layer was produced by mixing the following raw materials.

Resin A 0.7 parts by mass

Surfactant A 0.8 parts by mass

Propylene glycol monomethyl ether acetate (PGMEA) 98.5 parts by mass

The details of the raw materials are as follows.
Resin A: CYCLOMER P (ACA) 230AA (manufactured by DAICEL-ALLNEX LTD.; acid value=30 mgKOH/g, Mw=15000, 54% by mass PGME solution)
Surfactant A: 0.2% by mass PGMEA solution of a compound having the following structure (Mw=14000; numerical value “%” indicating the proportion of a repeating unit is mol %; fluorine-based surfactant)

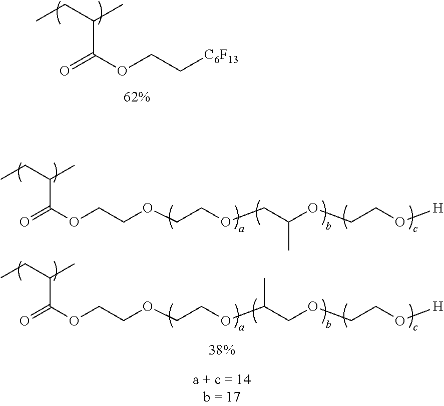

TABLE 16

| | Storage | Foreign | |
|---|---|---|---|
| | stability | matter | Spectroscopy |
| Example 1 | 5 | 5 | 5 |
| Example 2 | 5 | 5 | 5 |
| Example 3 | 5 | 5 | 5 |
| Example 4 | 5 | 5 | 5 |
| Example 5 | 5 | 5 | 5 |
| Example 6 | 5 | 5 | 5 |
| Example 7 | 4 | 4 | 5 |
| Example 8 | 4 | 4 | 5 |
| Example 9 | 5 | 5 | 5 |
| Example 10 | 4 | 4 | 5 |
| Example 11 | 4 | 4 | 5 |
| Example 12 | 4 | 4 | 5 |
| Example 13 | 4 | 4 | 5 |
| Example 14 | 4 | 4 | 5 |
| Example 15 | 4 | 4 | 5 |
| Example 16 | 4 | 4 | 5 |
| Example 17 | 4 | 4 | 5 |
| Example 18 | 4 | 4 | 5 |
| Example 19 | 4 | 4 | 5 |
| Example 20 | 5 | 5 | 5 |
| Example 21 | 5 | 5 | 5 |
| Example 22 | 4 | 4 | 5 |
| Example 23 | 4 | 4 | 5 |
| Example 24 | 5 | 5 | — |
| Example 25 | 5 | 5 | — |
| Example 26 | 4 | 4 | — |
| Example 27 | 4 | 4 | — |
| Example 28 | 5 | 5 | 5 |
| Example 29 | 5 | 5 | 5 |
| Example 30 | 5 | 5 | 5 |
| Example 31 | 5 | 5 | 5 |
| Example 32 | 5 | 5 | 5 |
| Example 33 | 5 | 5 | 5 |
| Example 34 | 5 | 5 | 5 |
| Example 35 | 5 | 5 | 5 |
| Example 36 | 5 | 5 | 5 |
| Example 37 | 5 | 5 | 5 |
| Example 38 | 5 | 5 | 5 |
| Example 39 | 5 | 5 | 5 |
| Example 40 | 5 | 5 | 5 |
| Example 41 | 5 | 5 | 5 |
| Example 42 | 5 | 5 | 5 |
| Example 43 | 5 | 5 | 5 |
| Example 44 | 5 | 5 | 5 |
| Example 45 | 5 | 5 | 5 |
| Example 46 | 5 | 5 | 5 |
| Example 47 | 5 | 5 | 5 |
| Example 48 | 5 | 5 | 5 |
| Example 49 | 4 | 4 | 5 |
| Example 50 | 4 | 4 | 5 |
| Example 51 | 4 | 4 | 5 |
| Example 52 | 4 | 4 | 5 |
| Example 53 | 5 | 5 | 5 |
| Example 54 | 5 | 5 | 5 |
| Example 55 | 5 | 5 | 5 |
| Example 56 | 4 | 4 | 5 |
| Example 57 | 5 | 5 | 5 |
| Example 58 | 5 | 5 | 5 |
| Example 59 | 5 | 5 | 5 |
| Example 60 | 5 | 5 | 5 |
| Example 61 | 5 | 5 | 5 |
| Example 62 | 5 | 5 | 5 |
| Example 63 | 5 | 5 | 5 |
| Example 64 | 5 | 5 | 5 |
| Example 65 | 5 | 5 | 5 |
| Example 66 | 5 | 5 | 5 |
| Example 67 | 5 | 5 | 5 |
| Example 68 | 5 | 5 | 5 |
| Example 69 | 5 | 5 | 5 |
| Example 70 | 5 | 5 | 5 |

TABLE 17

| | Storage | Foreign | |
|---|---|---|---|
| | stability | matter | Spectroscopy |
| Example 71 | 5 | 5 | 5 |
| Example 72 | 5 | 5 | 5 |
| Example 73 | 5 | 5 | 5 |
| Example 74 | 5 | 5 | 5 |
| Example 75 | 5 | 5 | 5 |
| Example 76 | 5 | 5 | 5 |
| Example 77 | 4 | 4 | 5 |
| Example 78 | 4 | 4 | 5 |
| Example 79 | 4 | 4 | 5 |
| Example 80 | 4 | 4 | 5 |
| Example 81 | 4 | 4 | 5 |
| Example 82 | 4 | 4 | 5 |
| Example 83 | 5 | 5 | 5 |
| Example 84 | 5 | 5 | 5 |
| Example 85 | 4 | 4 | 5 |
| Example 86 | 5 | 5 | — |
| Example 87 | 4 | 4 | — |
| Example 88 | 5 | 5 | 5 |
| Example 89 | 5 | 5 | 5 |
| Example 90 | 5 | 5 | 5 |
| Example 91 | 5 | 5 | 5 |
| Example 92 | 5 | 5 | 5 |
| Example 93 | 5 | 5 | 5 |
| Example 94 | 5 | 5 | 5 |
| Example 95 | 5 | 5 | 5 |
| Example 96 | 5 | 5 | 5 |
| Example 97 | 5 | 5 | 5 |
| Example 98 | 5 | 5 | 5 |
| Example 99 | 5 | 5 | 5 |
| Example 100 | 5 | 5 | 5 |
| Example 101 | 5 | 5 | 5 |
| Example 102 | 5 | 5 | 5 |
| Example 103 | 5 | 5 | 5 |
| Example 104 | 5 | 5 | 5 |
| Example 105 | 5 | 5 | 5 |
| Example 106 | 5 | 5 | 5 |
| Example 107 | 5 | 5 | 5 |
| Example 108 | 5 | 5 | 5 |
| Example 109 | 5 | 5 | 5 |
| Example 110 | 5 | 5 | 5 |
| Example 111 | 5 | 5 | 5 |
| Example 112 | 5 | 5 | 5 |
| Example 113 | 5 | 5 | 5 |
| Example 114 | 5 | 5 | 5 |
| Example 115 | 5 | 5 | 5 |
| Example 116 | 5 | 5 | 5 |
| Example 117 | 5 | 5 | 5 |
| Example 118 | 5 | 5 | 5 |
| Example 119 | 5 | 5 | 5 |
| Example 120 | 5 | 5 | 5 |
| Example 121 | 5 | 5 | 5 |
| Example 122 | 5 | 5 | 5 |
| Example 123 | 5 | 5 | 5 |
| Example 124 | 5 | 5 | 5 |
| Example 125 | 5 | 5 | 5 |
| Example 126 | 5 | 5 | 5 |
| Example 127 | 5 | 5 | 5 |
| Example 128 | 5 | 5 | 5 |

TABLE 18

| | Storage | Foreign | |
|---|---|---|---|
| | stability | matter | Spectroscopy |
| Comparative Example 1 | 1 | 1 | 1 |
| Comparative Example 2 | 1 | 1 | 1 |
| Comparative Example 3 | 1 | 1 | 1 |

As shown in the above tables, the resin compositions of Examples had good storage stability. Further, it was possible to form a film in which generation of foreign matter was suppressed. In addition, in Examples 1 to 23, 28 to 85, and 88 to 128, it was possible to form a film in which variation in spectral characteristics was suppressed.

### Example 1001

A composition for a base layer was applied to a silicon wafer by a spin coating method. Next, the composition was heated using a hot plate at 100° C. for 2 minutes and was further heated using a hot plate at 230° C. for 2 minutes. As a result, a base layer having a film thickness of 10 nm was formed. The composition for a base layer is the same as the composition for a base layer, which was used in the evaluation of foreign matter.

Next, the silicon wafer on which the base layer had been formed was coated with a green resin composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green resin composition was patterned by heating at 200° C. for 5 minutes using a hot plate to form a green pixel. In the same process, a red resin composition and a blue resin composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green resin composition, the resin composition of Example 99 was used. As the red resin composition, the resin composition of Example 79 was used. As the blue resin composition, the resin composition of Example 84 was used.

What is claimed is:

1. A resin composition comprising:
a pigment;
a compound A which includes 3 or more basic groups in one molecule, has an amine value of 2.7 mmol/g or more, and has a molecular weight of 100 or more; and
a resin having an acid group,
wherein the pigment is included in an amount of 40% by mass or more in a total solid content of the resin composition.

2. The resin composition according to claim 1,
wherein the basic group included in the compound A is an amino group.

3. The resin composition according to claim 1,
wherein the amine value of the compound A is 15 mmol/g or more.

4. The resin composition according to claim 1,
wherein the compound A is a polyalkyleneimine.

5. The resin composition according to claim 1,
wherein the compound A is polyethyleneimine.

6. The resin composition according to claim 1,
wherein the molecular weight of the compound A is 2000 or less.

7. The resin composition according to claim 1,
wherein the pigment includes a chromatic pigment.

8. The resin composition according to claim 1,
wherein the pigment includes a pigment containing a metal atom.

9. The resin composition according to claim 1,
wherein the pigment includes a halogenated zinc phthalocyanine pigment.

10. The resin composition according to claim 1,
wherein the pigment is included in an amount of 60% by mass or more in the total solid content of the resin composition.

11. The resin composition according to claim 1, further comprising:
a pigment derivative.

12. A film formed of the resin composition according to claim 1.

13. An optical filter comprising:
the film according to claim 12.

14. A solid-state imaging element comprising:
the film according to claim 12.

15. An image display device comprising:
the film according to claim 12.
